(19) United States
(12) Patent Application Publication
(10) Pub. No.: US 2017/0309566 A1
(43) Pub. Date: Oct. 26, 2017

(54) SEMICONDUCTOR INTEGRATED CIRCUIT DEVICE AND METHOD OF MANUFACTURING SEMICONDUCTOR INTEGRATED CIRCUIT DEVICE

(71) Applicant: Renesas Electronics Corporation, Tokyo (JP)

(72) Inventor: Naotake WATANABE, Tokyo (JP)

(73) Assignee: Renesas Electronics Corporation, Tokyo (JP)

(21) Appl. No.: 15/510,360

(22) PCT Filed: Sep. 11, 2014
(86) PCT No.: PCT/JP2014/074015

§ 371 Date: Mar. 10, 2017

(51) Int. Cl. H01L 23/525; H01L 21/70; G01R 31/28; H01L 21/82; H01L 27/11; H01L 29/72

(52) U.S. Cl. CPC H01L 23/5256; H01L 27/11; H01L 29/72; G01R 31/28; H01L 21/82; H01L 21/70; H01L 2924/0002

(57) ABSTRACT

A semiconductor integrated circuit device (1000) includes: a first semiconductor chip CHP1 having a first circuit; and a second semiconductor chip (CHP2) having a second circuit and differing from the first semiconductor chip (CHP1). The semiconductor integrated circuit device (1000) further includes a control circuit (BTCNT) for controlling an operation of the first circuit and an operation of the second circuit in accordance with a control signal in a burn-in test, and the control circuit (BTCNT) controls the first circuit and the second circuit such that an amount of stress applied to the first semiconductor chip (CHP1) due to an operation of the first circuit and an amount of stress applied to the second semiconductor chip (CHP2) due to an operation of the second circuit differ from each other in the burn-in test.

### TECHNICAL FIELD

The present invention relates to a semiconductor integrated circuit device and a method of manufacturing a semiconductor integrated circuit device. The present invention relates to, for example, a semiconductor integrated circuit device in which a plurality of semiconductor chips are mounted on one substrate and a method of manufacturing such a semiconductor integrated circuit device.

### BACKGROUND ART

It has been known that a failure rate of semiconductor chip changes along with time in accordance with a so-called bathtub characteristic. That is, to divide a time into an initial failure period, an accidental failure period and a wear-out failure period, the failure rate is lowered from a high value in the initial failure period, then maintains a low value in the accidental failure period, and is elevated again in the wear-out failure period. In the manufacture of the semiconductor integrated circuit devices, a stress is applied to the semiconductor integrated circuit devices, and the semiconductor integrated circuit devices which cause failure in the initial failure period are removed.

In steps of manufacturing semiconductor integrated circuit devices, such stress is applied in a burn-in test, for example. In the burn-in test, under a high temperature, a high power-source voltage is supplied to a semiconductor integrated circuit device so as to operate the semiconductor integrated circuit device. Accordingly, stress is applied to the semiconductor integrated circuit device, and a semiconductor integrated circuit device which causes a failure in an initial failure period becomes defective in the burn-in test so that such a defective semiconductor integrated circuit device can be removed.

The burn-in test is described in Patent Document 1, for example.

### RELATED ART DOCUMENT

### Patent Document

Patent Document 1: Japanese Patent Laid-open Publication No. 2004-226220

### SUMMARY OF THE INVENTION

### Problems to be Solved by the Invention

To realize high integration and/or downsizing of a mounting area, there has been known a so-called multi-chip module or multi-chip package where one semiconductor integrated circuit device is formed by mounting a plurality of semiconductor chips on one substrate and by sealing the semiconductor chips. In this case, the plurality of the semiconductor chips to be sealed may be the semiconductor chips of the same kind or may be the semiconductor chips of kinds differing from each other.

By forming the semiconductor chips of kinds differing from each other into one semiconductor integrated circuit device, it is possible to allow the semiconductor integrated circuit device to have higher functions or multi-functions while suppressing the increase of a cost. In this case, the plurality of respective semiconductor chips formed into one semiconductor integrated circuit device are manufactured by semiconductor manufacturing processes differing from each other. Accordingly, there may be a case where one semiconductor integrated circuit device is formed in a state where a semiconductor chip manufactured by an advanced semiconductor manufacturing process capable of realizing higher integration and a semiconductor chip manufactured by a previous generations' semiconductor manufacturing process capable of realizing the reduction of cost coexist. To show one example, one semiconductor integrated circuit device is formed by sealing a semiconductor chip manufactured by a semiconductor manufacturing process where a line width is set to 28 nm and a semiconductor chip manufactured by a semiconductor manufacturing process where a line width is set to 30 nm in one molded body.

Inventors of the present invention have found that the semiconductor chips manufactured by semiconductor manufacturing processes of different generations (for example, the generation where a line width is 28 nm and the generation where a line width is 30 nm) differ from each other in a bathtub characteristic which indicates a failure rate. For example, a bathtub characteristic of a semiconductor chip manufactured by an advanced semiconductor manufacturing process where a line width is small is shorter than a bathtub characteristic of a semiconductor chip manufactured by a previous generations' semiconductor manufacturing process. That is, a total time of an initial failure period, an accidental failure period and a wear-out failure period of a semiconductor chip manufactured by the advanced semiconductor manufacturing process is shorter than a corresponding total time of a semiconductor chip manufactured by the previous generations' semiconductor manufacturing process.

The inventors of the present invention have also found that when a plurality of semiconductor chips of different generations are sealed into one molded body and a burn-in test is performed on the semiconductor chips as one semiconductor integrated circuit device, a possibility is high that a failure occurs in the semiconductor chip manufactured by the more advanced semiconductor process. That is, there arises a case where a wear-out failure period of a semiconductor chip manufactured by an advanced semiconductor manufacturing process overlaps with an initial failure period of a semiconductor chip manufactured by a previous generations' semiconductor manufacturing process. Accordingly, in a burn-in test, when a stress corresponding to the initial failure period is applied to the semiconductor chip manufactured by the previous generations' semiconductor manufacturing process, stress corresponding to the wear-out failure period is applied to the semiconductor chip manufactured by the advanced semiconductor manufacturing process and sealed as the same semiconductor integrated circuit device. Accordingly, in the burn-in test, excessively large stress is applied to the semiconductor chip manufactured by the advanced semiconductor manufacturing process thus giving rise to a possibility that the number of semiconductor integrated circuit devices which are removed as defective devices is increased.

On the other hand, in the burn-in test, when stress corresponding to an initial failure period is applied to the semiconductor chip manufactured by the advanced semiconductor manufacturing process, the stress is not sufficient for the previous-generation semiconductor chips sealed in one molded body. Accordingly, it is difficult to remove a semiconductor integrated circuit device in which a semiconductor chip which may cause a failure in an initial failure period is sealed in the burn-in test.

Patent Document 1 merely discloses the burn-in test for semiconductor chip, and does not disclose a burn-in test for a semiconductor integrated circuit device formed by sealing a plurality of semiconductor chips. It is needless to say that Patent Document 1 also does not disclose any problems which may be caused when a burn-in test is performed with respect to a semiconductor integrated circuit device formed by sealing a plurality of semiconductor chips of different generations.

It is a preferred aim of the present invention to provide a semiconductor integrated circuit device having a plurality of semiconductor chips and capable of applying proper stresses to the respective semiconductor chips in a burn-in test.

Other object and novel characteristics of the present invention will be apparent from the description of the present specification and the accompanying drawings.

### Means for Solving the Problems

A plurality of means to solve the problems are disclosed in this specification. In this specification, only typical means for overcoming drawbacks are described.

A semiconductor integrated circuit device includes: a first semiconductor chip having a first circuit and a second semiconductor chip having a second circuit and differing from the first semiconductor chip. The semiconductor integrated circuit device further includes a control circuit for controlling an operation of the first circuit and an operation of the second circuit in accordance with a control signal in a burn-in test. The control circuit controls the first circuit and the second circuit such that an amount of stress applied to the first semiconductor chip due to an operation of the first circuit and an amount of stress applied to the second semiconductor chip due to an operation of the second circuit differ from each other in the burn-in test.

The semiconductor integrated circuit device is, in the burn-in test, brought into a high-temperature state (under a high temperature) and a high power source voltage is supplied to the semiconductor integrated circuit device. In the burn-in test, when the first circuit is operated, an electric current flows into, for example, an element(s) and/or a wiring(s) which forms the first circuit so that stress is generated and the generated stress is applied to the first semiconductor chip. In the same manner, in the burn-in test, when the second circuit is operated, an electric current flows into, for example, an element(s) and/or a wiring(s) which forms the second circuit so that a stress is generated and the generated stress is applied to the second semiconductor chip. The control circuit controls the first circuit and the second circuit such that an amount of stress applied to the first semiconductor chip due to an operation of the first circuit and an amount of stress applied to the second semiconductor chip due to an operation of a second circuit differ from each other. With such control, in the burn-in test, it is possible to apply amounts of stresses suitable for the first semiconductor chip and the second semiconductor chip respectively to the first semiconductor chip and the second semiconductor chip. As a result, it is possible to provide a semiconductor integrated circuit device having a high yield rate while maintaining reliability of the semiconductor integrated circuit device.

In an embodiment, the control circuit controls, in the burn-in test, the first circuit and the second circuit such that a time during which the first circuit is operated and a time during which the second circuit is operated differ from each other. By making the times during which the first circuit and the second circuit are operated respectively different from each other, it is possible to make an amount of stress generated in the first circuit and an amount of stress generated in the second circuit also different from each other.

Further, in the embodiment, the control circuit controls, in the burn-in test, the first circuit and the second circuit such that an operation speed of the first circuit and an operation speed of the second circuit differ from each other. By making the operation speed of the first circuit and the operation speed of the second circuit different from each other, an amount of stress per time differs and hence, an amount of stress generated in the first circuit and an amount of stress generated in the second circuit are made differ from each other.

### Effects of the Invention

According to an embodiment, it is possible to provide a semiconductor integrated circuit device which has a plurality of semiconductor chips, and can apply proper stresses to the respective semiconductor chips in a burn-in test.

### BRIEF DESCRIPTIONS OF THE DRAWINGS

FIG. 1 is a schematic plan view showing a configuration of a semiconductor integrated circuit device according to a first embodiment;

FIG. 2 is a schematic cross-sectional view showing the configuration of the semiconductor integrated circuit device according to the first embodiment;

FIGS. 3(A) and 3(B) are diagrams showing bathtub characteristics of semiconductor chips;

FIG. 4 is a block diagram showing the configuration of the semiconductor integrated circuit device according to the first embodiment;

FIGS. 5(A) and 5(B) are diagrams for describing a burn-in control circuit according to the first embodiment;

FIG. 6 is a block diagram showing the configuration of the burn-in control circuit according to the first embodiment;

FIG. 7 is a view for describing a mode of the semiconductor integrated circuit device according to the first embodiment;

FIGS. 8(A) to 8(C) are waveform diagrams for describing an operation of the burn-in control circuit according to the first embodiment;

FIGS. 9(A) and 9(B) are diagrams for describing an operation of the burn-in control circuit according to the first embodiment;

FIGS. 10(A) to 10(E) are diagrams for describing an operation of the burn-in control circuit according to the first embodiment;

FIG. 11 is a block diagram showing the configuration of a burn-in board according to the first embodiment;

FIG. 12 is a flowchart for manufacturing the semiconductor integrated circuit device according to the first embodiment;

FIG. 13 is a block diagram showing the configuration of a burn-in board according to a second embodiment;

FIGS. 14(A) and 14(B) are diagrams for describing an operation of the burn-in board according to the second embodiment; and

FIG. 15 is a block diagram showing a configuration of a semiconductor integrated circuit device according to a third embodiment.

### BEST MODE FOR CARRYING OUT THE INVENTION

Hereinafter, embodiments of the present invention will be described in detail with reference to the accompanying drawings. Note that the same components are denoted by the same reference symbols in principle throughout all the drawings for describing the embodiment, and the repetitive description thereof will be omitted.

### First Embodiment

<Overall Configuration of Semiconductor Integrated Circuit Device>

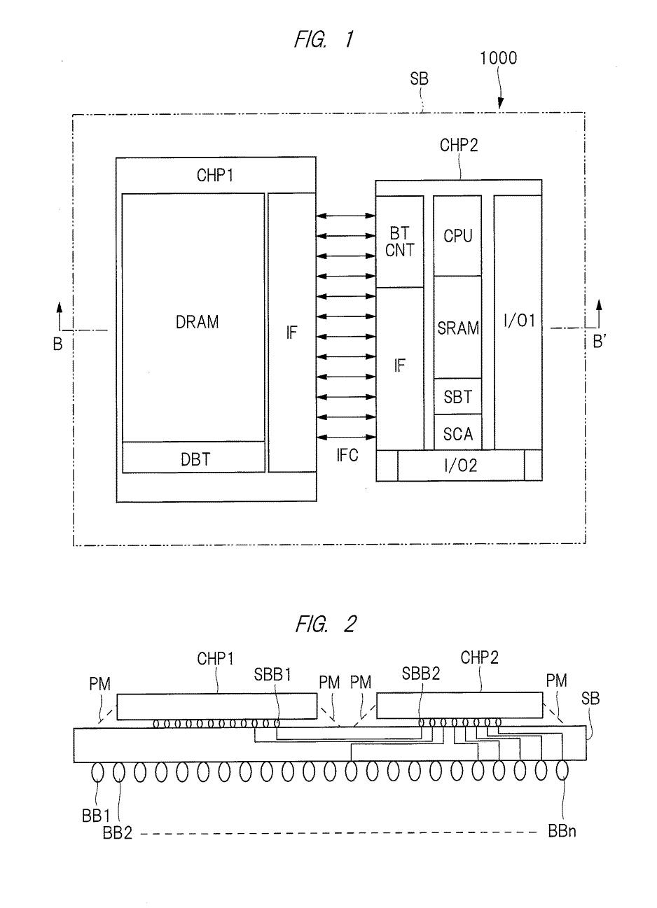

FIG. 1 is a schematic plan view showing the configuration of a semiconductor integrated circuit device according to a first embodiment. In FIG. 1, 1000 indicates a semiconductor integrated circuit device, SB indicates a substrate, and CHP1 and CHP2 respectively indicate semiconductor chips mounted on the substrate SB. FIG. 1 is a schematic view of the semiconductor integrated circuit device 1000 as viewed from above. A schematic cross section of the semiconductor integrated circuit device as viewed in cross section taken along a line B-B′ in FIG. 1 is shown in FIG. 2. In FIGS. 1 and 2, the semiconductor chip CHP1 and CHP2 are manufactured by semiconductor manufacturing processes which are different from each other. Although not particularly limited, on the semiconductor chip CHP1 (first semiconductor chip), a memory circuit (first circuit) such as a dynamic memory DRAM, an interface circuit IF and a test circuit DBT (first test circuit) are formed by a semiconductor manufacturing process where a line width is 30 nm, for example. The test circuit DBT is a built-in scan test circuit. The test circuit DBT generates a test pattern, supplies the generated test pattern to the dynamic memory DRAM, and operates the dynamic memory DRAM in accordance with the supplied test pattern.

On the other hand, on the semiconductor chip CHP2 (second semiconductor chip), a static memory SRAM (second circuit or third circuit), an interface circuit IF, a logic circuit (third circuit or second circuit), a test circuit and a burn-in control circuit BTCNT (control circuit) are formed by a semiconductor manufacturing process where a line width is 28 nm, for example. In this embodiment, the logic circuit includes a microcontroller CPU and input/output circuits I/O1, I/O2. The test circuit includes a test circuit SBT (second test circuit or third test circuit) for testing the static memory SRAM, and a test circuit SCA (third test circuit or second test circuit) for testing the logic circuit. The test circuit SBT for testing the static memory SRAM is a built-in scan test circuit. The test circuit SBT generates a test pattern, supplies the generated test pattern to the static memory SRAM, and operates the static memory SRAM in accordance with the supplied test pattern. The test circuit SCA is a scan pass circuit, is connected to a plurality of flip-flop circuits included in the logic circuit in series, supplies a test pattern to the flip-flop circuits connected in series, and operates the logic circuit in accordance with the test pattern.

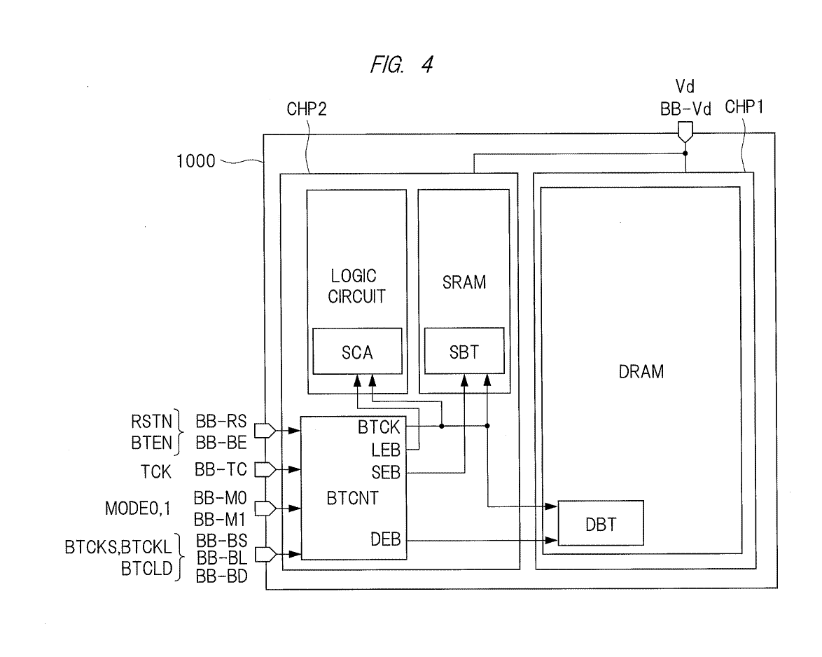

In the burn-in test, the burn-in control circuit BTCNT controls the test circuit DBT in the semiconductor chip CHP1 and the test circuits SBT and SCA in the semiconductor chip CHP2. The burn-in control circuit BTCNT is described in detail later with reference to FIGS. 4 to 11.

The transmission and reception of signals are performed between the semiconductor chips CHP1 and CHP2 using a plurality of interface signals IFC. For example, a control signal for controlling the test circuit DBT mounted on the semiconductor chip CHP1 by the burn-in control device BTCNT is included in the above-mentioned plurality of interface signals IFC. Although not particularly limited, the semiconductor integrated circuit device 1000 shown in FIG. 1 is a semiconductor integrated circuit device for high-speed serial communication. For example, high-speed serial data is supplied to the input/output circuit I/O1, and is supplied to the microcontroller CPU from the input/output circuit I/O1. The microcontroller CPU analyzes, for example, a protocol or the like of serial data using the static memory SRAM. Serial data obtained by conversion of parallel data or protocol is outputted from the input/output circuit I/O2.

The microcontroller CPU stores, for example, supplied serial data and/or parallel data or serial data to be outputted in the dynamic memory DRAM or reads out stored data from the dynamic memory DRAM. This storing and reading of data are performed in the form of transmission and reception of interface signals IFC through an interface circuit IF mounted on the semiconductor chips CHP1 and CHP2 respectively.

In this first embodiment, the semiconductor chips CHP1, CHP2 are respectively mounted on the substrate SB as shown in FIG. 2. Although the substrate SB is not particularly limited, the substrate SB is formed by laminating a plurality of insulation layers, and metal wirings are disposed between the insulation layers. Metal pads are formed on one main surface of the substrate SB (for example, an upper surface of the substrate SB in FIG. 2) and a surface of the substrate SB which is disposed on a side opposite to the main surface (a lower surface of the substrate SB in FIG. 2).

Predetermined metal pads are electrically connected to each other by the metal wirings formed between the insulation layers. Metal pads are also formed on respective main surfaces of the semiconductor chips CHP1, CHP2 (lower surfaces of the semiconductor chips CHP1, CHP2 in FIG. 2) and these metal pads are electrically connected to inputs and outputs of the respective circuits.

The metal pads formed on the main surface of the semiconductor chip CHP1 and the metal pads formed on one main surface of the substrate SB are electrically connected to each other through metal balls. The metal pads formed on the main surface of the semiconductor chip CHP2 and the metal pads formed on one main surface of the substrate SB are electrically connected to each other through metal balls. As shown in FIG. 2, a plurality of metal balls are disposed between the metal pads of the semiconductor chip CHP1 and the metal pads of the substrate SB. In FIG. 2, one metal ball is indicated by symbol SBB1 as the representative of the plurality of metal balls. In the same manner, as shown in FIG. 2, a plurality of metal balls are also disposed between the metal pads of the semiconductor chip CHP2 and the metal pads of the substrate SB. In FIG. 2, one metal ball is indicated by symbol SBB2 as the representative of the plurality of metal balls.

Further, metal balls BB1 to BBn are mounted also on metal pads formed on the lower surface of the substrate SB, and the metal pads are electrically connected to a printed substrate or the like not shown in the drawing through these metal balls, for example. Further, portions of theses metal balls BB1 to BBn are electrically connected to terminals of a burn-in board which is described later using FIG. 11 in a burn-in test. In FIG. 2, as the metal wirings disposed in the substrate SB, only some metal wirings which transmit interface signals IFC and metal wirings which connect the semiconductor chip CHP2 and the metal balls BBn or the like to each other are shown.

In FIG. 2, a broken line PM indicates a resin for sealing the semiconductor chips CHP1 and CHP2. In this embodiment, although not particularly limited, the respective semiconductor chips CHP1, CHP2 are sealed by a resin in such a manner that one-side surfaces of the semiconductor chips CHP1 and CHP2 are exposed, and connecting portions between the substrate SB and the semiconductor chips CHP1, CHP2 are covered by the resin.

In FIGS. 1 and 2, the semiconductor chips CHP1, CHP2 are mounted on the substrate SB such that the semiconductor chips CHP1, CHP2 are respectively disposed parallel to the substrate SB. However, mounting of the semiconductor chips CHP1, CHP2 is not limited to such mounting. For example, the semiconductor chip HP2 may be mounted on the semiconductor chip CHP1. That is, the semiconductor chips CHP1, CHP2 may be mounted in a stacked manner. Further, when a pitch of the metal pads formed on the surfaces of the semiconductor chips CHP1 and CHP2 and a pitch of the metal pads formed on the upper surface of the substrate SB do not agree with each other, a rewiring layer for pitch conversion may be formed on the semiconductor chips CHP1, CHP2 respectively, and the metal pads formed on the semiconductor chip and the metal pads formed on the substrate SB may be electrically connected to each other through the rewiring layer.

As described previously, the semiconductor chip CHP1 is manufactured by a semiconductor manufacturing process where a line width is 30 nm, and the semiconductor chip CHP2 is manufactured by a semiconductor manufacturing process more advanced than the semiconductor manufacturing process for manufacturing the semiconductor chip CHP1 where a line width is 28 nm. That is, in this embodiment, the semiconductor chip CHP2 is manufactured by the semiconductor manufacturing process more generation-advanced than the semiconductor manufacturing process for manufacturing the semiconductor chip CHP1. By manufacturing the semiconductor chip CHP1 by the previous generations' semiconductor manufacturing process, a cost of the semiconductor chip CHP1 can be lowered, for example. On the other hand, by manufacturing the semiconductor chip CHP2 by the advanced-generation semiconductor manufacturing process, the semiconductor chip CHP2 can be made finer so that it is possible to impart a large number of functions to the semiconductor chip CHP2, for example.

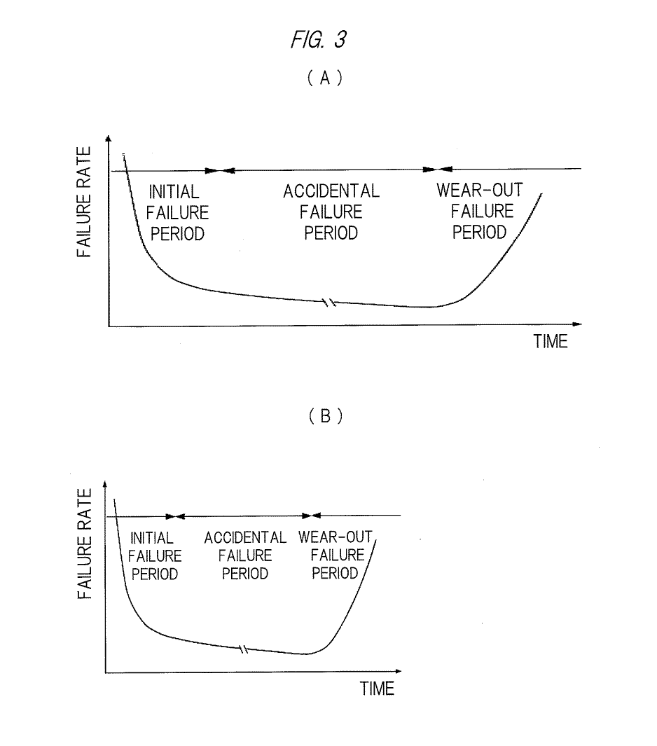

On the other hand, a bathtub characteristic of the semiconductor chip CHP2 manufactured by the advanced-generation semiconductor manufacturing process exhibits a curve shown in FIG. 3(B). On the other hand, a bathtub characteristic of the semiconductor chip CHP1 manufactured by the previous generations' semiconductor manufacturing process exhibits a curve shown in FIG. 3(A).

In FIGS. 3(A) and 3(B), time is taken on an axis of abscissas and a failure rate is taken on an axis of ordinates. In FIGS. 3(A) and 3(B), the same scale is used with respect to time. As can be understood from FIGS. 3(A) and 3(B), the semiconductor chip manufactured by the advanced-generation semiconductor manufacturing process exhibits a shorter period than the semiconductor chip manufactured by the previous generations' semiconductor manufacturing process during all of an initial failure period, an accidental failure period and a wear-out failure period.

Accordingly, when both of the semiconductor chips CHP1, CHP2 are operated for the same time in a burn-in test, a stress suitable for generating a failure which is generated during the initial failure period can be applied to the semiconductor chip CHP1, and a stress for generating a failure which is generated during the accidental failure period or a failure which is generated during the wear-out failure period is applied to the semiconductor chip CHP2. On the other hand, when a stress suitable for the semiconductor chip CHP2 is applied in a burn-in test, there arises a situation where a stress sufficient for generating a failure in the initial failure period is not applied to the semiconductor chip CHP1. That is, when the same amount of stress is applied to both of the semiconductor chips CHP1, CHP2, an excess or shortage of an amount of stress occurs in either one of the semiconductor chips CHP1, CHP2.

<Configuration of Semiconductor Integrated Circuit Device>

FIG. 4 is a block diagram showing the configuration of the semiconductor integrated circuit device 1000 according to this embodiment. In FIG. 4, BB-Vd, BB-RS, BB-BE, BB-TC, BB-M0, BB-M1, BB-BS, BB-BL and BB-BD respectively indicate some of metal balls BB1 to BBn shown in FIG. 2. Hereinafter, these metal balls are referred to as terminals. In this embodiment, among metal balls BB1 to BBn shown in FIG. 2, a voltage, a clock signal and a control signal are supplied to the terminals BB-Vd, BB-RS, BB-BE, BB-TC, BB-M0, BB-M1, BB-BS, BB-BL and BB-BD in a burn-in test.

The terminal BB-Vd is a power source voltage terminal. The power source voltage terminal BB-Vd is connected to the semiconductor chips CHP1 and CHP2 respectively. A dynamic memory DRAM, an interface circuit IF and a test circuit DBT included in the semiconductor chip CHP1 respectively receive a power source voltage Vd supplied to the power source voltage terminal BB-Vd and are operated using the power source voltage Vd as an operational voltage. In the same manner, the power source voltage Vd is supplied to a logic circuit, a static memory SRAM, an interface circuit IF, a burn-in control circuit BTCNT and test circuits SBT, SCA included in the semiconductor chip CHP2, and these circuits are operated using the power source voltage Vd as an operational voltage. To prevent the drawing from becoming complicated, in FIG. 4, the interface circuit IF is omitted, and the microcontroller CPU, the input/output circuits I/O1, I/O2 shown in FIG. 1 are indicated as a logic circuit. To facilitate the understanding of the correspondence relationship between the test circuit and a circuit which becomes a testing object, a test circuit DBT which performs a test of the dynamic memory DRAM is depicted such that the test circuit DBT is included in the dynamic memory DRAM. In the same manner, a test circuit SBT which performs a test of a static memory SRAM is depicted such that the test circuit SBT is included in the static memory SRAM, and a test circuit SCA which performs a test of a logic circuit is depicted such that the test circuit SCA is included in the logic circuit. However, these configurations are provided for facilitating the understanding of the mutual relationship between the test circuit and the circuit which becomes a testing object and hence, the present invention is not limited to such configurations.

The burn-in control circuit BTCNT generates a burn-in internal clock signal (hereafter also referred to as an internal clock signal) BTCK, a burn-in enable signal for logic (hereafter also referred to as an L enable signal) LEB, a burn-in enable signal for a static memory (hereafter also referred to as an S enable signal) SEB and a burn-in enable signal for a dynamic memory (hereafter also referred to as a D enable signal) DEB based on signals supplied from the terminals BB-RS, BB-BE, BB-TC, BB-M0, BB-M1, BB-BS, BB-BL and BB-BD. The test circuit DBT receives a D enable signal DEB and an internal clock signal BTCK, and forms a test pattern in accordance with an internal clock signal BTCK when the D enable signal DEB assumes a high level (logic value “1”), for example, and supplies the test pattern to the dynamic memory DRAM. The dynamic memory DRAM has a plurality of memory cells. When the test pattern is supplied to the dynamic memory DRAM, the memory cell is sequentially selected from the plurality of memory cells and a writing operation of the supplied test pattern to the selected memory cell is performed. Although not particularly limited, an internal clock signal BTCK supplied to the test circuit DBT is also supplied to the dynamic memory DRAM from the test circuit DBT, and a writing operation is performed in synchronization with the internal clock signal BTCK.

The test circuit SBT receives an S enable signal SEB and an internal clock signal BTCK, and forms a test pattern in accordance with an internal clock signal BTCK when the S enable signal SEB assumes a high level (logic value “1”), for example, and supplies the test pattern to the static memory SRAM. The static memory SRAM has a plurality of memory cells. When the test pattern is supplied to the static memory SRAM, the memory cell is sequentially selected from the plurality of memory cells and a writing operation of the test pattern to the selected memory cell is performed. Also in the test circuit SBT, although not particularly limited, an internal clock signal BTCK supplied to the test circuit SBT is supplied to the static memory SRAM. The static memory SRAM performs the above-mentioned writing operation in synchronization with the supplied internal clock signal BLCK.

The test circuit SCA receives an L enable signal LEB and an internal clock signal BTCK, and when the L enable signal LEB assumes a high level (logic value “1”), for example, the test circuit SCA generates a test control signal for connecting a plurality of flip-flop circuits included in the logic circuit in series. The test circuit SCA also generates a test pattern to be supplied to the flip-flop circuits connected in series, and supplies the generated test control signal and test pattern to the logic circuit. The logic circuit connects the plurality of flip-flop circuits included in the logic circuit in series in response to a test control signal, sets a test pattern in the flip-flop circuits connected in series, and starts an operation. Also in this case, the test circuit SCA supplies an internal clock signal BTCK to the logic circuit. The logic circuit performs a logic operation in synchronization with an internal clock signal BTCK using a test pattern set in the flip-flop circuit as an initial input signal, for example.

Although described later, the burn-in control circuit BTCNT receives: a reset signal RSTN and a burn-in enable signal BTEN supplied to the terminals BB-RS and BB-BE; a burn-in clock signal TCK supplied to the terminal BB-TC; and burn-in mode control signals MODE0, MODE1 (mode signals) supplied to the terminals BB-M0 and BB-M1. In this embodiment, the burn-in control circuit BTCNT also receives time counting clock signals BTCKS, BTCKL and BTCLD supplied to the terminals BB-BS, BB-BL and BB-BD respectively. Based on these received signals, the burn-in control circuit BTCNT generates and outputs an internal clock signal BTCK, a D enable signal DEB, an S enable signal SEB and an L enable signal LEB.

<Configuration and Manner of Operation of Burn-in Control Circuit BTCNT>

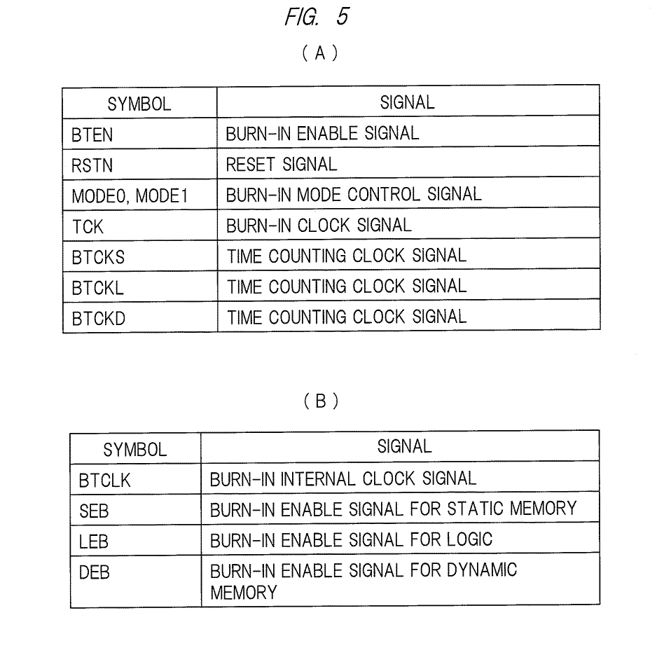

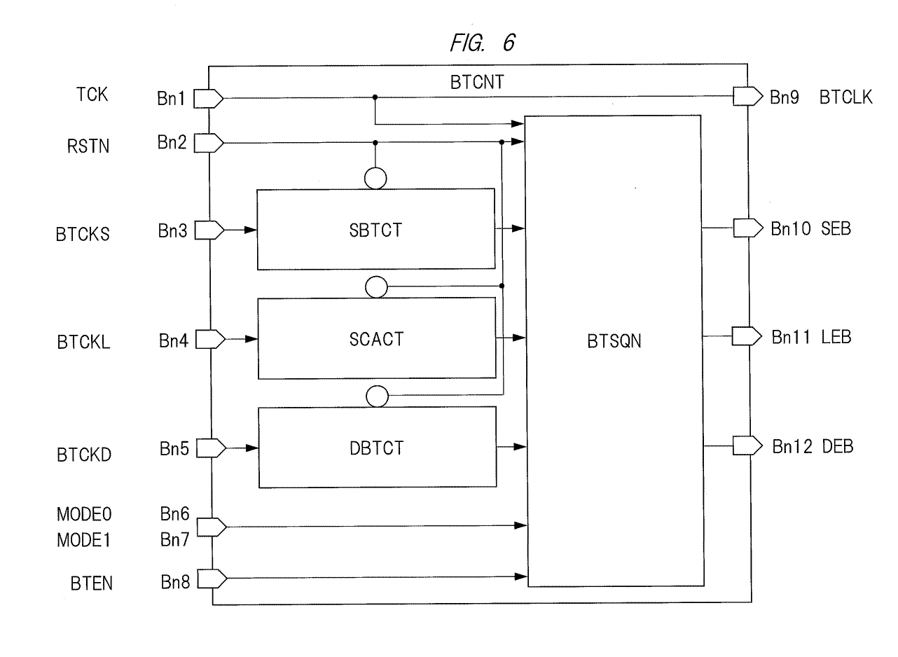

Next, the configuration and the manner of operation of the burn-in control circuit BTCNT are described with reference to FIGS. 5 to 10. First, the correspondence relationship between signals supplied to the burn-in control circuit BTCNT and signals outputted from the burn-in control circuit BTCNT and symbols affixed to the respective signals is explicitly described. FIG. 5(A) is a view showing the correspondence between a plurality of signals supplied to the burn-in control circuit BTCNT and symbols affixed to the respective signals. FIG. 5(B) is a view showing the correspondence between signals outputted from the burn-in control circuit BTCNT and symbols affixed to the respective signals. In FIGS. 6 to 10 used in the description relating to the burn-in control circuit BTCNT, symbols indicated in FIG. 5 are used.

<<Configuration of Burn-in Control Circuit BTCNT>>

FIG. 6 is a block diagram showing the configuration of the burn-in control circuit BTCNT. In this embodiment, as shown in FIGS. 1 and 4, the burn-in control circuit BTCNT is mounted on the semiconductor chip CHP2. That is, the burn-in control circuit BTCNT is formed on one semiconductor chip CHP2 together with the logic circuit and the static memory SRAM. Although not particularly limited, the burn-in control circuit BTCNT has input nodes Bn1 to Bn8 and output nodes Bn9 to Bn12. In FIG. 6, SBTCT indicates a burn-in time counter circuit (second designating circuit) for a static memory SRAM, SCACT indicates a burn-in time counter circuit (designating circuit) for a logic circuit, DBTCT indicates a burn-in time counter circuit (first designating circuit) for a dynamic memory DRAM, and BTSQN indicates a burn-in test sequence circuit (sequence circuit). The burn-in control circuit BTCNT includes these burn-in time counter circuits and burn-in test sequence circuits.

A burn-in clock signal TCK is supplied to the input node Bn1. The burn-in clock signal TCK supplied to the input node Bn1 is supplied to the burn-in test sequence circuit BTSQN and is supplied to the output node Bn9. The burn-in clock signal TCK supplied to the output node Bn9 is outputted from the burn-in control circuit BTCNT as a burn-in internal clock signal BTCLK.

A reset signal RSTN is supplied to the input node Bn2. The reset signal RSTN supplied to the input node Bn2 is supplied to the burn-in time counter circuits SBTCT, SCACT and DBTCT, and the burn-in test sequence circuit BTSQN. In FIG. 6, a circular mark affixed to the burn-in time counter circuits SBTCT, SCACT and DBTCT respectively indicates input nodes of phase inversion. These input nodes are reset input nodes of the respective burn-in time counter circuits. Accordingly, assuming that, for example, a logic value “1” (high level) indicates an effective state, when a reset signal RSTN assumes a low level (logic value “0”), the burn-in time counter circuits SBTCT, SCACT and DBTCT are respectively reset. By such resetting, the respective burn-in time counter circuits SBTCT, SCACT and DBTCT assume an initial count value (for example, “0”).

The burn-in time counter circuit SBTCT receives a time counting clock signal BTCKS supplied through the input node Bn3 and counts the time counting clock signal BTCKS. The burn-in time count circuit SCACT receives a time counting clock signal BTCKL supplied through the input node Bn4 and counts the time counting clock signal BTCKL. In the same manner, the burn-in time count circuit DBTCT receives a time counting clock signal BTCKD supplied through the input node Bn5 and counts the time counting clock signal BTCKD. For example, after a counted value is reset and becomes an initial count value, the burn-in time count circuit SBTCT counts the number of times that a logic value of the received time counting clock signal BTCKS changes from a logic value “0” (low level) to a logic value “1” (high level), and the burn-in time counter circuit SBTCT outputs a time arrival signal when the number of times reaches a predetermined count value. After outputting the time arrival signal, the burn-in time count circuit SBTCT again counts the number of times that a logic value of the time counting clock signal BTCKS changes from the initial count value. Thereafter, this counting operation is repeated. The burn-in time count circuits SCACT and DBTCT are also reset in the same manner as the burn-in time count circuit SBTCT. That is, after a counted value is reset and becomes an initial count value, the burn-in time counter circuits SCACT and DBTCT count the numbers of times that logic values of the received time counting clock signals BTCKL, BTCKD change from a logic value “0” (low level) to a logic value “1” (high level), and the burn-in time counter circuits SCACT and DBTCT output time arrival signals when the numbers of times reach predetermined count values. After outputting the time arrival signals, the burn-in time count circuits SCACT and DBTCT again respectively count the numbers of times that logic values of the time counting clock signals BTCKL, BTCKD change from the initial count values. Thereafter, this counting operation is repeated.

In this embodiment, the burn-in time counter circuit SBTCT is a burn-in time counter circuit for a static memory SRAM which is provided for counting a time count clock signal BTCKS for a static memory SRAM. The burn-in time counter circuit SCACT is a burn-in time counter circuit for a logic circuit which is provided for counting a time count clock signal BTCKL for a logic circuit. In the same manner, the burn-in time counter circuit DBTCT is a burn-in time counter circuit for a dynamic memory DRAM which is provided for counting a time count clock signal BTCKD for a dynamic memory DRAM.

Time arrival signals which are outputted from the burn-in time counter circuits SBTCT, SCACT and DBTCT respectively are supplied to the burn-in test sequence circuit BRSQN.

The burn-in test sequence circuit BRSQN receives burn-in mode control signals MODE0, MODE1 through the input nodes Bn6 and Bn7 and receives a burn-in enable signal BTEN through the input node Bn8 together with time arrival signals from the above-mentioned burn-in clock signal TCK and burn-in time counter circuits SBTCT, SCACT and DBTCT. In this embodiment, the burn-in enable signal BTE is a signal for designating whether or not the burn-in control circuit BTCNT is to be operated. The burn-in mode control signals MODE0, MODE1 are signals for designating an operation mode of the burn-in control circuit BTCNT in the burn-in test. Although not particularly limited, in this embodiment, the burn-in control circuit BTCNT has a stop mode, a reset mode and four kinds of operation modes.

<<Mode Selection of Burn-in Control Circuit BTCNT>>

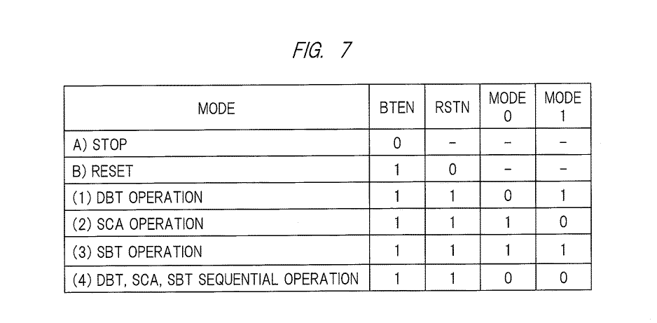

Next, the mode selection of the burn-in control circuit BTCNT is described with reference to FIG. 7. FIG. 7 shows, as a table, the correspondence between the combinations of a burn-in enable signal BTEN, a reset signal RSTN and burn-in mode control signals MODE0, MODE1 and the operation modes of the burn-in control circuit BTCNT. In the table shown in FIG. 7, in the column of modes, the operation modes of the burn-in control circuit BTCNT are indicated. Further, in this table, logic values of the burn-in enable signal BTEN, the reset signal RSTN, the burn-in mode control signal MODE0 and the burn-in mode control signal MODE1 are indicated in the column of BTEN, the column of RSTN, the column of MODE0, and the column of MODE′. Also in the table, a logic value “1” indicates “valid”.

The burn-in test sequence circuit BTSQN disposed in the burn-in control circuit BTCNT determines an operation mode of the burn-in control circuit BTCNT in accordance with the table shown in FIG. 7. That is, when a logic value of a burn-in enable signal BTEN is set at “0”, the burn-in control circuit BTCNT is brought into a stop state (“A) stop”). On the other hand, when a logic value of a burn-in enable signal BTEN is set at “1” and a logic value of a reset signal RSTN is set at “0”, the burn-in control circuit BTCNT is brought into a reset state (“B) reset”). In such a reset state, the burn-in time counter circuits SBTCT, SCACT and DBTCT are also reset respectively as described previously. Logic values of the reset signal RSTN and the burn-in mode control signals MODE0, MODE1 have no significance in a stop state and hence, the logic values are indicated by “-” in FIG. 7. In the same manner, logic values of the burn-in mode control signals MODE0, MODE′ have no significance in a reset state and hence, the logic values are indicated by “-” in FIG. 7.

When a logic value of a burn-in enable signal BTEN is set to “1” and a logic value of a reset signal RSTN is set at “1”, the burn-in test sequence circuit BTSQN determines an operation mode of the burn-in control circuit BTCNT in accordance with burn-in mode control signals MODE0 and MODE1.

That is, when a logic value of a burn-in mode control signal MODE0 is set to “0” and a logic value of a burn-in mode control signal MODE1 is set to “1”, the burn-in test sequence circuit BTSQN sets a D enable signal DEB at a high level and sets an S enable signal SEB and an L enable signal LEB at a low level respectively. With such processing, a test circuit DBT which corresponds to the dynamic memory DRAM is brought into an operation state ((1) DBT operation). At this stage of processing, remaining test circuits SCA and SBT are held in a non-operation state.

Next, when a logic value of a burn-in mode control signal MODE0 is set to “1” and a logic value of a burn-in mode control signal MODE1 is set to “0”, the burn-in test sequence circuit BTSQN sets an L enable signal LEB at a high level and sets a D enable signal DEB and an S enable signal SEB at a low level respectively. With such processing, a test circuit SCA which corresponds to the logic circuit is brought into an operation state ((2) SCA operation). At this stage of processing, remaining test circuits DBT and SBT are held in a non-operation state.

when a logic value of a burn-in mode control signal MODE0 is set to “1” and a logic value of a burn-in mode control signal MODE1 is set to “1”, the burn-in test sequence circuit BTSQN sets an S enable signal SEB at a high level and sets a D enable signal DEB and an L enable signal LEB at a low level respectively. With such processing, a test circuit SBT which corresponds to the static memory SRAM is brought into an operation state ((3) SBT operation). At this stage of processing, remaining test circuits SCA and DBT are held in a non-operation state.

Further, when a logic value of a burn-in mode control signal MODE0 is set to “0” and a logic value of a burn-in mode control signal MODE1 is set to “0”, the burn-in test sequence circuit BTSQN sequentially sets a D enable signal DEB, an L enable signal LEB and an S enable signal SEB at a high level in accordance with a predetermined sequence. In this case, the burn-in test sequence circuit BTSQN is configured such that two or more enable signals are not substantially simultaneously set at a high level. With such processing, the test circuit DBT which corresponds to the dynamic memory DRAM, the test circuit SCA which corresponds to the logic circuit and the test circuit SBT which corresponds to the static memory SRAM are sequentially operated ((4) DBT, SCA, SBT sequential operation). In this sequential operation, two or more test circuits are not allowed to be substantially operated simultaneously.

In accordance with the combination of the burn-in mode control signals MODE0, MODE1, voltages (logic values) of an S enable signal, an L enable signal and a D enable signal are determined, and an operation/non-operation of the test circuits SBT, SCA and DBT is determined based on the voltages of the respective enable signals. Accordingly, burn-in mode control signals MODE0, MODE1 are regarded as mode control signals which determine an operation mode of the semiconductor integrated circuit device 1000 when the semiconductor integrated circuit device 1000 is in a burn-in test.

<<Manner of Operation of Burn-in Test Sequence Circuit BTSQN>>

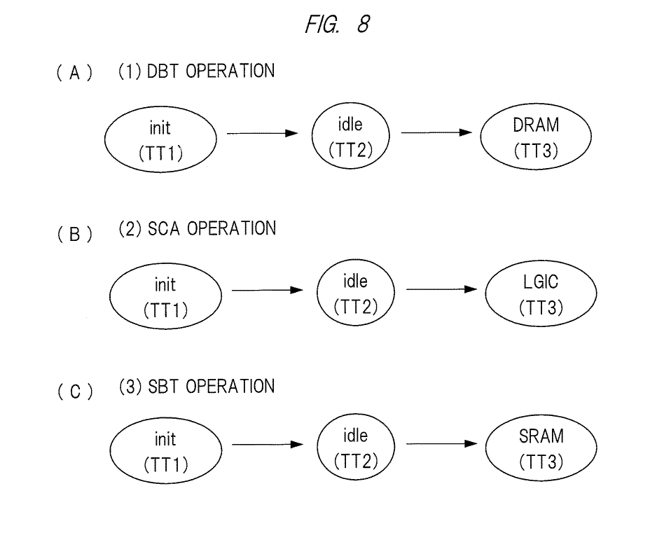

When the burn test sequence circuit BTSQN determines an operation mode in accordance with the table shown in FIG. 7, the burn-in control circuit BTCNT is operated in accordance with the determined operation mode. An operation of the burn-in control circuit BTCNT in the respective operation modes is described with reference to FIGS. 8 to 10. FIG. 8(A) shows a sequence executed in the above-mentioned operation mode “(1) DBT operation”. FIG. 8(B) shows a sequence executed in the operation mode “(2) SCA operation”. FIG. 8(C) shows a sequence executed in the operation mode “(3) SBT operation”.

The sequence executed in the operation mode “(1) DBT operation”, the sequence executed in the operation mode “(2) SCA operation” and the sequence executed in the operation mode “(3) SBT operation” are similar to each other. That is, an initializing operation (init) is executed first, a standby state (idle) is brought about and, thereafter, the test circuits which correspond to the respective operation modes are operated.

In this embodiment, the initializing operation (init) is an operation which is performed during a period where a logic value of a burn-in enable signal BTEN is set at “0” (low level). As such an initializing operation, in a case where a fuse is provided to the dynamic memory DRAM and/or the static memory SRAM, for example, an operation of reading information from the fuse is performed. In a case where the dynamic memory DRAM and/or the static memory SRAM have/has a defective part (for example, a defective memory cell), the fuse may be a fuse for redundancy which changes the defective part into a redundancy part. For example, failure information which expresses the presence/non-presence of a defective part and address information of a defective part (when the defective part exists) are written in the fuse for redundancy in a step of manufacturing the semiconductor integrated circuit device 1000. Information is read out from the fuse during a period TT1 of the initializing operation (init).

Next, when the logic value of a burn-in enable signal BTEN is changed to “1” (high level), in accordance with the combination of burn-in mode control signals MODE0 and MODE1 at this stage of processing, any one of a D enable signal DEB, an L enable signal LEB and a D enable signal DEB is set as a high level. In this case, although not particularly limited, the burn-in test sequence circuit BTSQN sets an enable signal which conforms to the combination of burn-in mode control signals MODE0 and MODE1 at a high level after a burn-in clock signal TCK is generated a predetermined number of times. A time ensured by the predetermined number of times becomes a time TT2 in a standby state (idle). The number of predetermined times may be two to the second power with respect to a burn-in clock signal TCK. A period (TT1) for the initializing operation (init) may be, for example, two to the fourteenth power of burn-in clock signals TCK, and this time is ensured as a period for initializing.

The operation mode “(1) DBT operation”, the operation mode “(2) SCA operation” and the operation mode “(3) SBT operation” are respectively continued until a logic value of a reset signal RSTN or a burn-in enable signal BTEN becomes “0” (low level). That is, for example, example, when the operation mode “(1) DBT operation” is designated, a logic value of a D enable signal DEB is continuously held at “1” (high level) until a logic value of a reset signal RSTN or a burn-in enable signal BTEN becomes “0” (low level). The same processing is executed when the operation mode “(2) SCA operation” or the operation mode “(3) SBT operation” is designated. That is, a logic value of an L enable signal LEB or an S enable signal SEB is continuously held at “1”.

With such processing, among three test circuits DBT, SCA and SBT, only the test circuit which receives an enable signal having a logic value “1” is continuously operated, and the test circuits which receive an enable signal having a logic value “0” are held in a non-operative state. When the test circuit is brought into an operative state, only a circuit (dynamic memory DRAM, static memory SRAM or logic circuit) to which a test pattern or the like is supplied from the test circuit in an operative state is operated in a burn-in test. As a result, during the burn-in test, it is possible to apply a stress to only one of either the semiconductor chip CHP1 or the semiconductor chip CHP2 mounted on the same semiconductor integrated circuit device 1000 in a sealed manner.

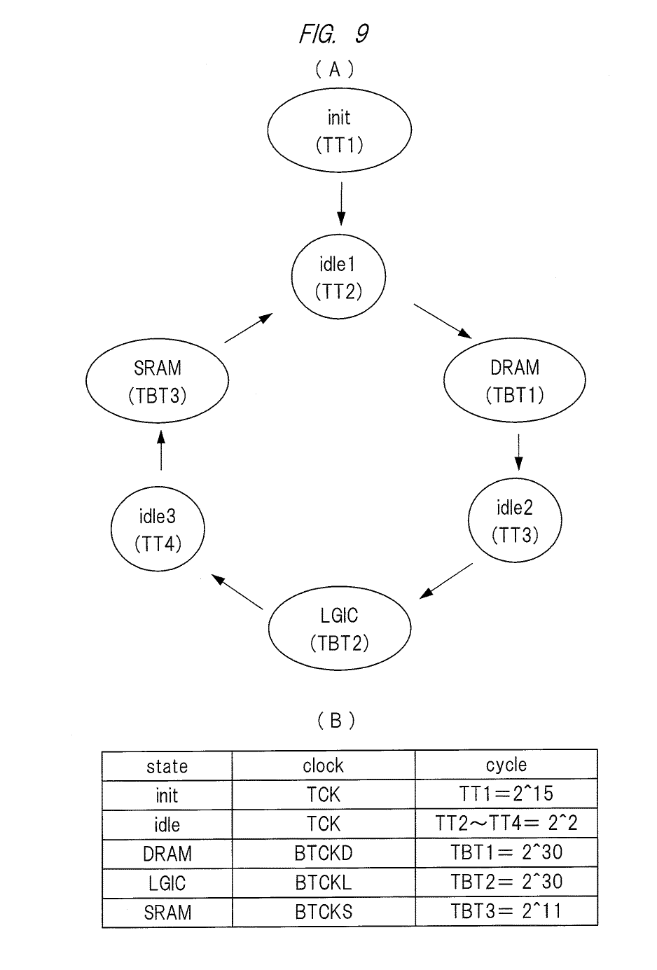

Next, the manner of operation of the burn-in control circuit BTCNT in the operation mode “(4) DBT, SCA, SBT sequential operation” is described. FIG. 9(A) is a transition diagram showing a sequence operation of the burn-in control circuit BTCNT executed in the operation mode “(4) DBT, SCA, SBT sequential operation”. FIG. 9(B) is a view showing one example of times of operations which are sequentially executed.

In the operation mode “(4) DBT, SCA, SBT sequential operation”, the burn-in test sequence circuit BTSQN sequentially sets a logic value of a D enable signal DEB, a logic value of an L enable signal LEB and a logic value of an S enable signal SEB at “1” (high level) in predetermined order. In this embodiment, for the sake of convenience of description, it is assumed that the burn-in test sequence circuit BTSQN sets the respective logic values at “1” in order of the D enable signal DEB, the L enable signal LEB and the S enable signal SEB. It is needless to say that the order is not limited to such order and the order may be set as desired.

In FIG. 9(A), an initializing operation (init) is equal to the initializing operation (init) described with reference to FIGS. 8(A) to 8(C) and hence, the description of the initializing operation (init) is omitted.

As has been described with reference to FIG. 8, when a logic value of a burn-in enable signal BTEN is set to “1”, after a standby state (idle′) is finished, the burn-in control circuit BTCNT sets a logic value of a D enable signal DEB to “1”. Accordingly, an operation of the test circuit DEB (FIG. 4) which corresponds to the dynamic memory DRAM is started. As the test circuit DEB is operated, a test pattern and a burn-in internal clock signal BTCLK are supplied to a dynamic memory DRAM from the test circuit DEB so that the dynamic memory DRAM is operated (described as DRAM in FIG. 9). When the dynamic memory DRAM is operated, a stress is applied to the semiconductor chip CHP1.

Although described later, a time (TBT1) during which a logic value of a D enable signal DEB is maintained at “1” can be changed as desired. After the desired time (TBT1) elapses, the burn-in control circuit BTCNT sets a logic value of the D enable signal DEB at “0” so that an operation state is transcended to a standby state (idle2). After the standby state (idle2) is maintained for a predetermined time TT3, the burn-in control circuit BTCNT sets a logic value of an L enable signal LEB at “1”. Accordingly, an operation of the test circuit SCA (FIG. 4) which corresponds to the logic circuit is started. When the test circuit SCA is operated, a test control signal, a test pattern and a burn-in internal clock signal BTCLK are supplied to the logic circuit from the test circuit SCA. In the logic circuit, flip-flop circuits are connected to each other in series in response to the supplied test control signal, and a test pattern is supplied to the flip-flop circuits connected to each other in series. Using the test pattern held in the flip-flop circuits as an initial input, the logic circuit is operated in accordance with the burn-in internal clock signal BTCLK (described as LGIC in FIG. 9). When the logic circuit is operated, a stress is applied to the semiconductor chip CHP2.

At a point of time when a desired time (TBT2) elapses from starting an operation of the logic circuit, the burn-in control circuit BTCNT changes a logic value of an L enable signal LEB to “0” so that an operation state is transcended to a standby state (idle3). The standby state (idle3) is maintained for a predetermined time TT4 and, after the predetermined time TT4 elapses, the burn-in control circuit BTCNT sets a logic value of an S enable signal SEB at “1”.

When a logic value of an S enable signal SEB is set at “1”, an operation of the test circuit SBT which corresponds to the static memory SRAM is started. When the test circuit SBT is operated, a test pattern and a burn-in internal clock signal BTCLK are supplied to the static memory SRAM from the test circuit SBT. In accordance with a burn-in internal clock signal BTCLK, a test pattern is sequentially written in the static memory SRAM, for example. When the test pattern is sequentially written in the static memory SRAM, a stress is applied to the semiconductor chip CHP2.

At a point of time when a desired time elapses from starting an operation of the test circuit SBT (described as SRAM in FIG. 9), the burn-in control circuit BTCNT changes a logic value of an S enable signal SEB to “0” so that an operation state is transcended to a standby state (idle2).

When a predetermined time (TT2) elapses in the standby state (idle2), the logic value of the D enable signal DEB is again set at “1”. Thereafter, the above-mentioned operation is repeated. This repeated operation is performed until a logic value of a reset signal RSTN and/or a burn-in enable signal BTEN are/is set at “0”, for example. It is needless to say that the above-mentioned operations may be repeated for a preset time or preset number of times.

FIG. 9(B) shows one example of the respective times necessary for the above-mentioned initializing operation, standby state, operation state of the dynamic memory DRAM, operation state of the logic circuit and operation state of the static memory SRAM. In FIG. 9(B), with respect to the initializing (init) operation, a period during which a burn-in clock signal TCK is generated two to the fifteenth power times is set as a time TT1 for initializing, and times for respective standby states (TT2 to TT4) are set to times (TT2 to TT4) where a burn-in clock signal TCK is generated to two to the second power times.

A period during which the dynamic memory DRAM is operated is set as a time TBT1 where a time counting clock signal BTCKD is generated two to the thirtieth power times. A period during which a logic circuit is operated is set as a time TBT2 where a time counting clock signal BTCKL is generated two to the thirtieth power times. A period during which the static memory SRAM is operated is set as a time TBT 3 during which a time counting clock signal BTCKS is generated two to the eleventh power.

In three respective standby states (idle1 to idle3), logic values of three enable signals DEB, LEB and SEB are set at “0”. Accordingly, in the respective standby states (idle1 to idle3), none of the dynamic memory DRAM, the logic circuit and the static memory SRAM is operated. Accordingly, it is possible to prevent a plurality of circuit from being simultaneously operated and hence, it is possible to suppress the increase in power consumption of a semiconductor integrated circuit device in a burn-in test.

During a period (TBT1) where the dynamic memory DRAM is operated (described as DRAM in FIG. 9(A)), is regarded as a time during which the dynamic memory DRAM generates a stress in a burn-in test and the stress is applied to the semiconductor chip CHP1. Accordingly, this period TBT1 can be regarded as a dwell time during which the stress generated by the dynamic memory DRAM stays. In the same manner, the period TBT2 can be regarded as a dwell time during which the stress generated by the logic circuit stays, and the period TBT3 can be regarded as a dwell time during which the stress generated by the static memory SRAM stays.

It is possible to acquire a total dwell time of a stress generated by the dynamic memory DRAM in a burn-in test, a total dwell time of a stress generated by the logic circuit in the burn-in test, and a total dwell time of a stress generated by the static memory SRAM in the burn-in test based on products obtained by multiplying the number of times that the above-mentioned sequential operation is repeated by the respective dwell times. Accordingly, it is possible to grasp amounts of stresses applied to the semiconductor chips CHP1, CHP2 from the dynamic memory DRAM, the logic circuit and the static memory SRAM.

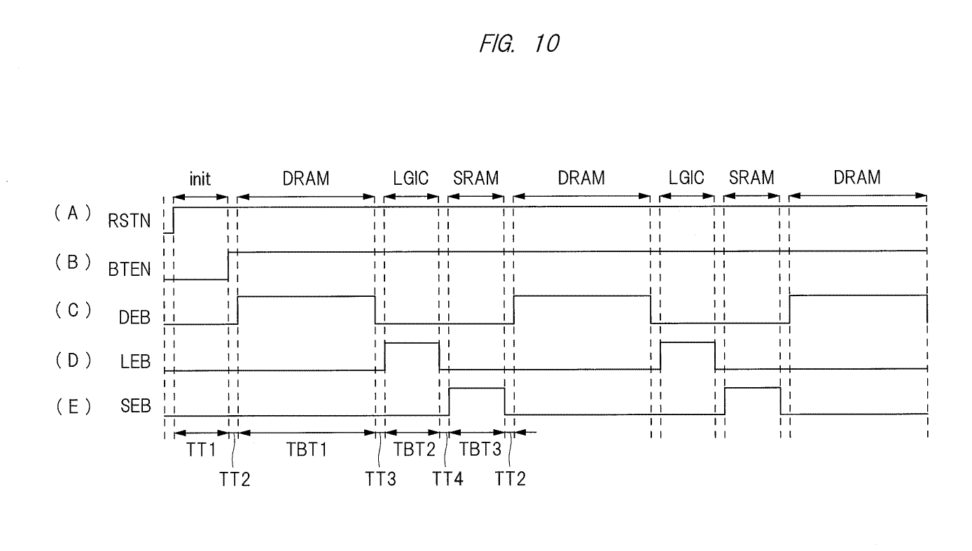

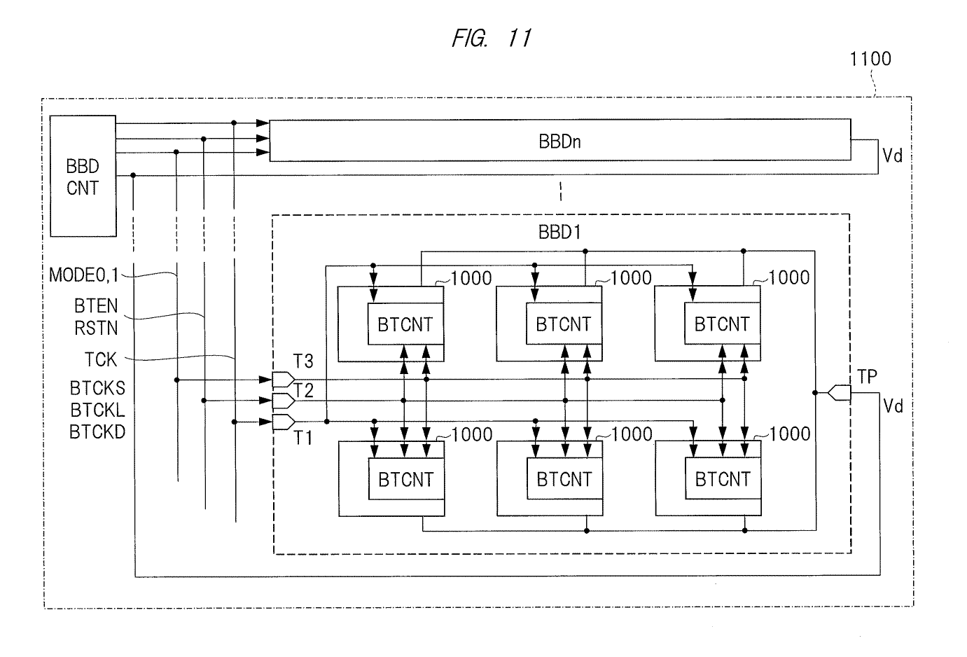

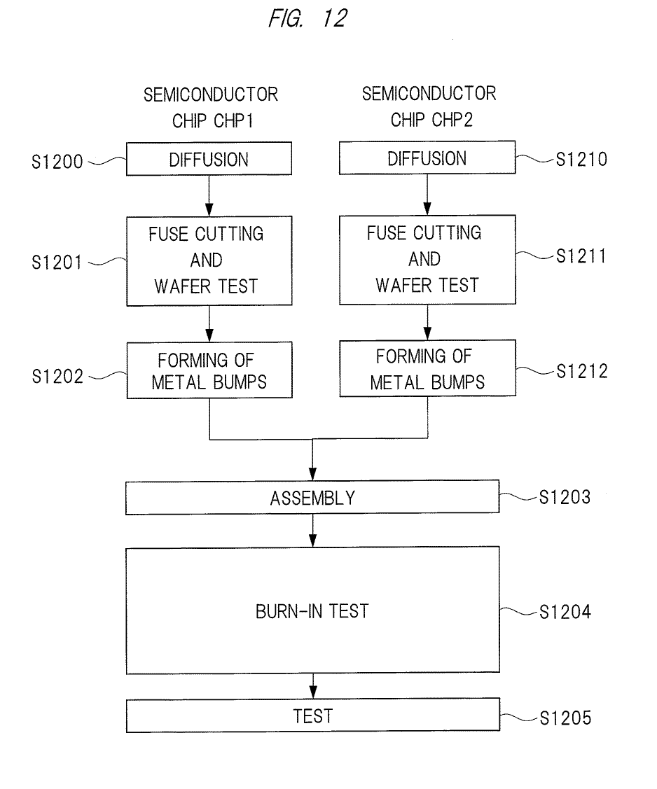

FIG. 10 is a waveform chart showing an operation of the burn-in control circuit BTCNT. In FIG. 10, time is taken on an axis of abscissas, and voltage is taken on an axis of ordinates. FIG. 10 shows waveforms generated when operation modes “(4) DBT, SCA, SBT sequential operations” are designated based on burn-in mode control signals MODE0 and MODE′. A high level corresponds to a logic value “1”, and a low level corresponds to a logic value “0”. In this embodiment, FIG. 10(A) shows a waveform of a reset signal RSTN, FIG. 10(B) shows a waveform of a burn-in enable signal BTEN, FIG. 10(C) shows a waveform of a D enable signal DEB, FIG. 10(D) shows a waveform of an L enable signal LEB, and FIG. 10(E) shows a waveform of an S enable signal SEB.

When a reset signal RSTN is changed from a low level to a high level, the semiconductor integrated circuit device 1000 is transcended to the above-mentioned initial state (init). Then, when a burn-in enable signal BTEN is changed to a high level, the burn-in control circuit BTCNT is transcended to a standby state (idle′) so that a D enable signal DEB, an L enable signal LEB and an S enable signal SEB are set at a low level respectively during a predetermined time (TT2). After the predetermined time (TT2) elapses, the burn-in control circuit BTCNT sets the D enable signal DEB at a high level, and maintains the respective remaining signals, that is, the L enable signal LEB and the S enable signal SEB at a low level. The burn-in control circuit BTCNT maintains this state during a desired dwell time (TBT1).

When the desired dwell time (TBT1) elapses, the burn-in control circuit BTCNT sets the D enable signal DEB at a low level again, and maintains the D enable signal DEB in a standby state (idle2) for a predetermined time (TT3). When the predetermined time (TT3) elapses, the burn-in control circuit BTCNT changes the L enable signal LEB to a high level, and maintains the L enable signal LEB at the high level during a desired dwell time (TBT2). During this dwell time (TBT2), both the D enable signal DEB and the S enable signal SEB are maintained at a low level. When the dwell time (TBT2) elapses, the burn-in control circuit BTCNT sets the L enable signal SEB at a low level, and the L enable signal SEB is held in a standby state (idle3) during the predetermined time (TT4). When the predetermined time (TT4) elapses, the burn-in control circuit BTCNT sets the S enable signal at a high level, and maintains the respective remaining enable signals DEB, LEB at a low level.

When a desired dwell time (TBT3) elapses, the burn-in control circuit BTCNT is again transcended to the standby state (TT2). Thereafter, the above-mentioned sequence operation is repeated.

<<Setting of Dwell Time>>

Next, setting of a dwell time is described mainly using FIG. 6, FIGS. 9 and 10. As has been described with reference to FIG. 6, the burn-in control circuit BTCNT includes: the burn-in time counter circuit SBTCT for the static memory SRAM; the burn-in time counter circuit SCACT for the logic circuit; and the burn-in time counter circuit DBTCT for the dynamic memory DRAM. The burn-in time counter SBTCT counts the number of clocks of a time counting clock signal BTCKS which corresponds to the static memory SRAM, and generates a time arrival signal each time the number of counted clocks reaches a predetermined count value. In the same manner, the burn-in time counter SCACT counts the number of clocks of a time counting clock signal BTCKL which corresponds to the logic circuit, and generates a time arrival signal each time the number of counted clocks reaches a predetermined count value. The burn-in time counter DBTCT counts the number of clocks of a time counting clock signal BTCKD which corresponds to the dynamic memory DRAM, and generates a time arrival signal each time the number of counted clocks reaches a predetermined count value.

With such a configuration, by changing frequencies of the time counting clock signals supplied to the respective burn-in time counter circuits, times during which time arrival signals are formed can be changed. To exemplify an example with reference to FIG. 9(B), the burn-in time counter circuit DBTCT for the dynamic memory DRAM sets, as a predetermined count value, a value which is obtained by counting the time counting clock signal BTCKD two to the thirtieth power times. Accordingly, the burn-in time counter circuit DBTCT generates a time arrival signal when the number of clocks of the time counting clock signal BTCKD which corresponds to the dynamic memory DRAM are counted two to the thirtieth power times, and supplies the time arrival signal to the burn-in test sequence circuit BTSQN.

In the same manner, the burn-in time counter circuit SCACT for the logic circuit sets, as a predetermined count value, a value which is obtained by counting the time counting clock signal BTCKL two to the thirtieth power times. Accordingly, the burn-in time counter circuit SCACT generates a time arrival signal when the number of clocks of the time counting clock signal BTCKL which corresponds to the logic circuit are counted two to the thirtieth power times, and supplies the time arrival signal to the burn-in test sequence circuit BTSQN. The burn-in time counter circuit SBTCT for the static memory SRAM sets, as a predetermined count value, a value which is obtained by counting the time counting clock signal BTCKS two to the eleventh power times. Accordingly, the burn-in time counter circuit SBTCT generates a time arrival signal when the number of clocks of the time counting clock signal BTCKS which corresponds to the static memory SRAM are counted two to the eleventh power times, and supplies the time arrival signal to the burn-in test sequence circuit BTSQN.

In this embodiment, when an operation mode “(4) DBT, SCA, SBT sequential operation” is designated based on burn-in mode control signals MODE0, MODE1 the burn-in test sequence circuit BTSQN counts the number of clocks of the burn-in clock signal TCK when a burn-in enable signal BTEN is set at a high level, and when the count value reaches two to the second power times, as shown in FIG. 10, a D enable signal DEB is set at a high level. Then, when a time arrival signal is supplied to the burn-in test sequence circuit BTSQN from the burn-in time counter circuit DBTCT for the dynamic memory DRAM, in response to the supply of the time transmission signal, the burn-in test sequence circuit BTSQN changes the D enable signal DEB to a low level.

Further, in response to a time arrival signal from the burn-in time counter circuit DBTCT, the burn-in test sequence circuit BTSQN counts the number of clocks of a burn-in clock signal TCK. When the count value reaches two to the second power times, the burn-in test sequence circuit BTSQN changes an L enable signal LEB to a high level as shown in FIG. 10. Then, when a time arrival signal is supplied to the burn-in test sequence circuit BTSQN from the burn-in time counter circuit SCACT for the logic circuit, in response to the supply of the time arrival signal, the burn-in test sequence circuit BTSQN changes the L enable signal LEB to a low level. Further, in response to a time arrival signal from the burn-in time counter circuit SCACT, the burn-in test sequence circuit BTSQN counts the number of clocks of a burn-in clock signal TCK. When the count value reaches two to the second power times, the burn-in test sequence circuit BTSQN changes an S enable signal SEB to a high level as shown in FIG. 10. Then, when a time arrival signal is supplied to the burn-in test sequence circuit BTSQN from the burn-in time counter circuit SBTCT for the static memory SRAM, in response to the supply of the time arrival signal, the burn-in test sequence circuit BTSQN changes the S enable signal SEB to a low level.

When a time arrival signal is supplied from the burn-in time counter circuit SBTCT, in response to the supply of the time arrival signal, the burn-in test sequence circuit BTSQN counts the number of clocks of the burn-in clock signal TCK. When the count value reaches two to the second power times, the burn in test sequence circuit BTSQN changes a D enable signal DEB to a high level again. Thereafter, such a sequence operation is repeated.

With such processing, by changing the respective frequencies of the time counting clock signals BTCKD, BTCKL and BTCLD, the respective dwell times TBT1 to TBT3 can be set as desired. That is, in a burn-in test, a time during which the dynamic memory DRAM is operated, a time during which the logic circuit is operated and a time during which the static memory SRAM is operated can be set as desired. Accordingly, in the burn-in test, it is possible to adjust an amount of stress applied to the semiconductor chip CHP1 from the dynamic memory DRAM and an amount of stress applied to the semiconductor chip CHP2 from the logic circuit and the static memory SRAM.

In this embodiment, the case is described where a dwell time is set by changing a frequency of a time counting clock signal. However, this case is one example, and the present invention is not limited by such a case. For example, predetermined count values set in the respective burn-in time counter circuits may be changed and clock signals supplied to the burn-in time counter circuits may have a fixed frequency.

<Configurations of Burn-in Board and Burn-in Test Device>

FIG. 11 is a schematic view schematically showing the configuration of the burn-in test device 1100. In FIG. 11, BBD1 to BBDn respectively indicate burn-in boards, and BBDCNT indicates a control device which controls the respective burn-in boards BBD1 to BBDn in a burn-in test. In the burn-in test, although not shown in the drawing, the burn-in test device 1100 bring the burn-in boards BBD1 to BBDn into a high-temperature state by a temperature adjusting mechanism. The control device BBDCNT supplies a reset signal RSTN, a burn-in enable signal BTEN, a burn-in clock signal TCK, burn-in mode control signals MODE0, MODE1, and time counting clock signals BTCKS, BTCKL, BTCKD to the burn-in boards BBD1 to BBDn correspondingly. The control device BBDCNT also supplies a power source voltage Vd to the respective burn-in boards BBD1 to BBDn. The power source voltage Vd is set to a high voltage in the burn-in test.

Although not particularly limited, in this embodiment, the respective burn-in boards BBD1 to BBDn have the same configuration. Accordingly, in FIG. 11, only the burn-in board BBD1 is described in detail. Hereinafter, the configuration of the burn-in board is described using the burn-in board BBD1 as a representative example.

In performing the burn-in test, the plurality of semiconductor integrated circuit devices 1000 are mounted on the burn-in board BBD1. Accordingly, a plurality of contact terminals (not shown in the drawing) which correspond to the respective semiconductor integrated circuit devices 1000 are formed on the burn-in board BBD1 in advance. The plurality of contact terminals which correspond to the respective semiconductor integrated circuit devices 1000 are connected to the control device BBDCNT through wirings and terminals which are formed on the burn-in board BBD1 in advance. The contact terminals include a contact terminal which receives a power source voltage Vd. With respect to these wirings and terminals, FIG. 11 explicitly shows: a terminal TP which receives a power source voltage Vd from the control device BBDCNT; a terminal T1 which receives a burn-in clock signal TCK and time counting clock signals BTCKS, BTCKL, BTCKD, a terminal T2 which receives a reset signal RSTN and a burn-in enable signal BTEN; and a terminal T3 which receives burn-in mode control signals MODE0, MODE′. FIG. 11 also explicitly shows wirings which connect these terminals T1 to T3, TP and the contact terminals with each other.

FIG. 11 shows a state where the plurality of semiconductor integrated circuit devices 1000 are mounted on the burn-in board BBD1 for a burn-in test. The respective semiconductor integrated circuit devices 1000 have the configurations shown in FIGS. 1 and 2. Mounting of the plurality of semiconductor integrated circuit devices 1000 on the burn-in board BBD1 is performed by electrically connecting metal balls BB1 to BBn of the semiconductor integrated circuit devices 1000 to the contact terminals which correspond to the semiconductor integrated circuit devices 1000. Although not particularly limited, to perform such electrical connection of the plurality of semiconductor integrated circuit devices 1000 to the burn-in board BBD1 with certainty, the respective semiconductor integrated circuit devices 1000 are pressure-bonded to the burn-in board BBD1. With such a configuration, in the burn-in test, signals from the control device BBDCNT (TCK, BTCKS, BTCKL, BTCKD, RSTN, BTEN, MODE0, MODE1) and a power source voltage Vd are supplied to the plurality of semiconductor integrated circuit devices 1000 mounted on the burn-in board BBD1.

Although only the burn-in control circuit BTCNT is explicitly described in each semiconductor integrated circuit device 1000 shown in FIG. 11, it should be understood that the semiconductor integrated circuit device 1000 also has semiconductor chips CHP1 and CHP2 as shown in FIG. 1. FIG. 11 also explicitly shows that the above-mentioned signals (TCK, BTCKS, BTCKL, BTCKD, RSTN, BTEN, MODE0, MODE1) are supplied to the burn-in control circuit BTCNT of each semiconductor integrated circuit device 1000. On the other hand, a power source voltage Vd is supplied to the respective semiconductor integrated circuit devices 1000, and is used as an operation voltage for operating respective circuit blocks formed in the respective semiconductor chips CHP1, CHP2 in the semiconductor integrated circuit device 1000.

In the burn-in test, a power source voltage Vd is supplied from the control device BBDCNT, and a voltage value of the power source voltage Vd is set higher than a voltage value adopted when the semiconductor integrated circuit device 1000 is used usually. With such a voltage, when the circuit block (the dynamic memory DRAM, the static memory SRAM, the logic circuit or the like) in the semiconductor chip CHP1, CHP2 is operated, for example, a value of an electric current which flows in an element (transistor, for example) which forms the circuit block becomes higher than a value of an electric current which the semiconductor integrated circuit device 1000 usually uses. Accordingly, a stress higher than a usual stress is applied to the element and/or lines. As a result, when a circuit block is operated in a burn-in test, a stress is applied to the semiconductor chip which includes the operated circuit.

In the burn-in test, the control device BBDCNT determines burn-in mode control signals MODE0, MODE1. Accordingly, in the burn-in test, the respective semiconductor integrated circuit devices 1000 are operated by any one of the above-mentioned four operation modes (“(1) DBT operation”, “(2) SCA operation”, “(3) SBT operation” and “(4) DBT, SCA, SBT sequential operation”). For example, when the semiconductor integrated circuit device 1000 is operated in the operation mode “(1) DBT operation”, in the burn-in test, the dynamic memory DRAM is operated. In this case, a stress is applied to the semiconductor chip CHP1 from the dynamic memory DRAM and hence, the stress is applied only to the semiconductor chip CHP1. When the semiconductor integrated circuit device 1000 is operated in the operation mode “(2) SCA operation”, in the burn-in test, the logic circuit is operated, and a stress is applied to the semiconductor chip CHP2 from the logic circuit. In this case, the stress is applied only to the semiconductor chip CHP2.

In the same manner, when the semiconductor integrated circuit device 1000 is operated in the operation mode “(3) SBT operation”, in the burn-in test, the static memory SRAM is operated and hence, a stress is applied to the semiconductor chip from the static memory SRAM whereby the stress is applied only to the semiconductor chip CHP2. Due to such a configuration, amounts of stress suitable for the respective semiconductor chips can be applied to the respective semiconductor chips CHP1, CHP2 in accordance with bathtub characteristics of the respective semiconductor chips CHP1, CHP2. For example, as shown in FIGS. 3(A) and 3(B), when the bathtub characteristic of the semiconductor chip CHP2 is shorter than the bathtub characteristic of the semiconductor chip CHP1, a time during which the semiconductor integrated circuit device 1000 is operated in the operation mode “(2) SCA operation” and/or “(3) SBT operation” is set shorter than a time during which the semiconductor integrated circuit device 1000 is operated in the operation mode “(1) DBT operation”. With such time setting, an amount of stress applied to the semiconductor chip CHP2 can be made small compared to an amount of stress applied to the semiconductor chip CHP1. As a result, amounts of stresses suitable for two respective semiconductor chips included in the same semiconductor integrated circuit device 1000 can be applied to the two respective semiconductor chips in a burn-in test.

As described above, by combining three operation modes (“(1) DBT operation”, “(2) SCA operation”, “(3) SBT operation”) with each other, amounts of stress suitable for the respective semiconductors chips CHP1, CHP2 can be applied to the respective semiconductors chip CHP1, CHP2 in a burn-in test. Further, in this embodiment, with the use of the operation mode “(4) DBT, SCA, SBT sequential operation”, amounts of stress suitable for the respective semiconductor chips CHP1, CHP2 can be applied to the semiconductor chips CHP1, CHP2 in the burn-in test even when the operation modes are not combined with each other.

When the control device BBCNT designates the operation mode “(4) DBT, SCA, SBT sequential operation” with respect to the respective semiconductor integrated circuit devices 1000, in each semiconductor integrated circuit device 1000, the dynamic memory DRAM, the logic circuit and the static memory SRAM are sequentially operated. Further, dwell times during which respective circuits are operated are determined based on respective frequencies of the time counting clock signals BTCKS, BTCKL, BTCKD. Accordingly, times during which the respective circuits are operated are obtained in accordance with bathtub characteristics of the respective semiconductor chips, frequencies of the time counting clock signals with which dwell times which correspond to the obtained time are obtained are set, and such frequencies of the time counting clock signals are supplied to the respective semiconductor integrated circuit devices 1000 from the control device BBCNT. With such processing, even when the operation modes are not combined with each other, in the burn-in test, the respective circuits can be sequentially operated and hence, times during which the respective circuits are operated can be also set as dwell times during which suitable amounts of stress are applied to the semiconductor chips.

For example, in the case of bathtub characteristics shown in FIGS. 3(A) and 3(B), the control device BBCNT designates an operation mode “(4) DBT, SCA, SBT sequential operation” in response to the burn-in mode control signals MODE0, MODE1 with respect to the respective semiconductor integrated circuit devices 1000. Further, the control device BBCNT forms a time counting clock signal BTCKD having a frequency lower than that of time counting clock signals BTCKS, BTCKL, and supplies the time counting clock signal BTCKD to the respective semiconductor integrated circuit devices 1000. By supplying such a time counting clock signal BTCKD, a time during which the dynamic memory DRAM formed in the semiconductor chip CHP1 is operated (dwell time) becomes long. Accordingly, out of two semiconductor chips formed in the same semiconductor integrated circuit device 1000, an amount of stress applied to the semiconductor chip CHP1 in the burn-in test can be increased and hence, the burn-in test suitable for each semiconductor chip can be performed.

The burn-in test is performed in a state where the burn-in test device 1100 is brought into a high temperature state. By operating the respective semiconductor integrated circuit devices 1000 in the operation mode “(4) DBT, SCA, SBT sequential operation”, amounts of stresses suitable for the respective semiconductor chips CHP1, CHP2 can be applied to the semiconductor chips CHP1, CHP2 while maintaining the burn-in test device 1100 in a high temperature state. The suitable amounts of stress can be applied to the respective semiconductor chips CHP1, CHP2 while maintaining the burn-in test device 1100 in a high temperature state and hence, a time required for performing the burn-in test can be shortened.

In the burn-in test, the description has been made with respect to the case where the semiconductor integrated circuit devices 1000 are operated by the combination of the operation modes (“(1) DBT operation”, “(2) SCA operation”, “(3) SBT operation”). These operation modes are also effectively used for obtaining bathtub characteristics of two respective semiconductor chips CHP1, CHP2 mounted on the semiconductor integrated circuit device 1000. For example, in a state where the semiconductor integrated circuit device 1000 is brought into a high temperature state and a high power source voltage is applied to the semiconductor integrated circuit device 1000, when the semiconductor integrated circuit device 1000 is operated in the operation mode “(1) DBT operation”, only the dynamic memory DRAM is operated. Accordingly, in this case, a failure rate of the semiconductor integrated circuit device 1000 corresponds to a failure rate of the semiconductor chip CHP1. By changing a time during which the semiconductor integrated circuit device 1000 is operated in the operation mode “(1) DBT operation” and by obtaining a failure rate of the semiconductor integrated circuit device 1000 in such a state, a bathtub characteristic of the semiconductor chip CHP1 can be obtained.

In the same manner, by operating the semiconductor integrated circuit device 1000 in an operation mode “(2) SCA operation” and/or “(3) SBT operation”, only the logic circuit and/or the static memory SRAM formed in the semiconductor chip CHP2 are/is operated. Accordingly, in this case, a failure rate of the semiconductor integrated circuit device 1000 corresponds to a failure rate of the semiconductor chip CHP2. Accordingly, also in this case, by changing a time during which the semiconductor integrated circuit device 1000 is operated in the operation mode “(2) SCA operation” and/or “(3) SBT operation” and by obtaining a failure rate of the semiconductor integrated circuit device 1000 in such a state, a bathtub characteristic of the semiconductor chip CHP2 can be obtained.

A burn-in test is performed based on the respective bathtub characteristics of the semiconductor chips CHP1, CHP2 which are obtained in this manner. In this case, in the burn-in test, the control device BBDCNT designates an operation mode “(4) DBT, SCA, SBT sequential operation” with respect to the burn-in control circuit BTCNT of the semiconductor integrated circuit device 1000. Based on the bathtub characteristics of the respective semiconductors chip CHP1, CHP2 obtained in advance, a dwell time during which the dynamic memory DRAM is operated, a dwell time during which the logic circuit is operated and a dwell time during which the static memory SRAM is operated are set. Further, frequencies of the respective time counting clock signals BTCKD, BTCKL and BTCKD are set. The respective dwell times and the respective time counting clock signals are supplied to the burn-in control circuit BTCNT. Accordingly, the burn-in test can be performed while applying amounts of stresses suitable for bathtub characteristics of two respective semiconductor chips included in the semiconductor integrated circuit device 1000.

<Method of Manufacturing Semiconductor Integrated Circuit Device 1000>

FIG. 12 is a flowchart showing a method of manufacturing a semiconductor integrated circuit device 1000. A semiconductor chip CHP1 is manufactured through steps S1200 to S1202, and a semiconductor chip CHP2 is manufactured through steps S1210 to S1212.

First, a method of manufacturing the semiconductor chip CHP1 is described. In step S1200, a semiconductor region where elements such as transistors are formed in accordance with a circuit pattern of a dynamic memory DRAM and the like is formed on a semiconductor wafer by processing such as diffusion. Lines and the like which electrically connect the formed semiconductor region and the like are formed by etching processing. With such processing, in step S1200, a plurality of semiconductor chips each of which includes a dynamic memory DRAM and the like are formed on the semiconductor wafer. In FIG. 12, a plurality of processing for forming the semiconductor chip are collectively indicated as one step S1200. “diffusion” is indicated as a representative example of processing which is executed in this step. In this embodiment, in step S1200, a circuit pattern is formed on the semiconductor wafer by a semiconductor manufacturing process where a line width is 30 nm.

Next, in step S1201, writing of information in a redundant fuse and a test of the semiconductor wafer are performed (fuse cutting and wafer test). In this step, writing of information to the redundant fuse described previously is executed. Tests are also performed on the respective semiconductor chips formed on the semiconductor wafer.

In step S1202, metal bumps (SBB1, for example) shown in FIG. 2 are mounted on metal pads of each semiconductor chip formed on the semiconductor wafer (forming of the metal bumps). In an assembly step S1203, when a pitch of the wirings disposed on a substrate SB (FIG. 2) and a pitch of the metal pads of the semiconductor chips do not agree with each other, pitch changing members are mounted on the semiconductor wafer in step S1202 between the metal pads of the semiconductor chip and the metal bumps (for example, SBB1 in FIG. 2), and the metal pads and the metal bumps are connected to each other through the pitch changing member.

On the other hand, with respect to the semiconductor chip CHP2, in step S1210, a semiconductor region where elements such as transistors are formed in accordance with a circuit pattern of a static memory SRAM, a logic circuit, a burn-in control circuit BTCNT and the like is formed on a semiconductor wafer by processing such as diffusion. Wirings and the like which electrically connect the formed semiconductor region and the like are formed by etching processing. With such processing, in step S1210, a plurality of semiconductor chips each of which includes a static memory SRAM, a logic circuit, a burn-in control circuit BTCNT and the like are formed on the semiconductor wafer. In FIG. 12, a plurality of processing for forming the semiconductor chip are collectively indicated as one step S1210. “Diffusion” is indicated as a representative example of such processing. In this embodiment, in step S1210, a circuit pattern is formed on the semiconductor wafer by a semiconductor manufacturing process where a line width is 28 nm.

Next, in step S1211, in the same manner as step S1201, cutting of a fuse and a test of the semiconductor wafer are performed (fuse cutting and wafer test). In step S1212, in the same manner as step S1202, metal bumps (for example, SBB2 in FIG. 2) are formed. It is needless to say that, in step S1212, pitch changing members are mounted on the semiconductor wafer when necessary.

The semiconductor wafers on which the metal bumps are formed in step S1202 and step S1212 respectively are assembled as a semiconductor integrated circuit device 1000 in step S1203 (assembly). That is, although it is not particularly limited, each semiconductor wafer is cut into the plurality of semiconductor chips. The semiconductor chips which are obtained by cutting form semiconductor chips CHP1 and CHP2. That is, the plurality of semiconductor chips provided to step S1203 through steps S1200 to S1202 and obtained by cutting the semiconductor wafer in step S1203 form the semiconductor chips CHP1. In the same manner, the plurality of semiconductor chips provided to step S1203 through steps S1210 to S1212 and obtained by cutting the semiconductor wafer in step S1203 form the semiconductor chips CHP2.

The semiconductor chips CHP1 and CHP2 obtained by cutting the semiconductor wafers are mounted on the substrate SB such that the metal bumps are connected to the wirings of the substrate SB (FIG. 2).

The mounted semiconductor chips CHP1, CHP2 are sealed by a resin or the like as indicated by a broken line PM in FIG. 2. With such processing, the semiconductor integrated circuit device 1000 which includes the semiconductor chips CHP1 and CHP2 is prepared.

In burn-in test step S1204, a burn-in test is performed on the plurality of semiconductor integrated circuit devices 1000 which are assembled in step S1203. In this case, as shown in FIG. 11, the burn-in test is performed in a state where the plurality of semiconductor integrated circuit devices 1000 are stored in a burn-in test device 1100. That is, substantially simultaneously, the plurality of semiconductor integrated circuit devices 1000 are brought into a high-temperature state, and a high power source voltage Vd is supplied to the plurality of semiconductor integrated circuit devices 1000. As described previously, in the burn-in test, for example, a burn-in control circuit BTCNT is set to be operated in accordance with an operation mode “(4) DBT, SCA, SBT sequential operation”. In this operation, the dynamic memory DRAM, the logic circuit and the static memory SRAM are operated in this order. Here, a time during which the dynamic memory DRAM is operated, a time during which the logic circuit is operated and a time during which the static memory SRAM is operated (holding times) are set in accordance with bathtub characteristics of the semiconductor chips CHP1, CHP2.

In the burn-in test, a high voltage (high power source voltage Vd) is supplied to the semiconductor integrated circuit devices 1000 in a high-temperature state. However, amounts of stresses applied to the respective semiconductor chips CHP1, CHP2 formed on the semiconductor integrated circuit device 1000 are controlled separately. Accordingly, suitable amounts of stress can be applied to the semiconductor chips in burn-in test step S1204.

Step S1205 is a step of testing the semiconductor integrated circuit devices 1000. Although not particularly limited, test step S1205 includes a plurality of test steps. For example, in burn-in test step S1204, stresses are applied to the respective semiconductor integrated circuit devices 1000 so that a defective semiconductor integrated circuit device 1000 may be found. The semiconductor integrated circuit device 1000 which turns out to be a defective semiconductor integrated circuit device 1000 in burn-in test step S1205 is sorted in test step S1205. A test which is performed by a purchaser who purchases the semiconductor integrated circuit devices 1000 is also included in test step S1205.

It is needless to say that a defective semiconductor integrated circuit device may be sorted in burn-in test step S1204. In this case, for example, a comparison circuit is provided where expected values for test patterns generated by the test circuits DBT, SBT, SCA and outputs from the dynamic memory DRAM, the logic circuit and the static memory SRAM are compared with each other, and it is determined that a semiconductor integrated circuit device is defective when the expected values and the outputs do not agree with each other as a result of the comparison made by the comparison circuit. Processing for manufacturing semiconductor chips from the semiconductor wafer by cutting may be performed in step S1202, S1212.

Steps S1200 to S1202 where the semiconductor chips CHP1 are manufactured and steps S1210 to S1212 where the semiconductor chips CHP2 are manufactured may not be performed parallel in time. Further, steps S1200 to S1202 and steps S1210 to S1212 may be performed at places geographically remote from each other. Step S1200 and step S1210 differ from each other in a semiconductor manufacturing process and hence, the semiconductor chips CHP1 and the semiconductor chips CHP2 may be manufactured by different semiconductor manufacturers.

According to the first embodiment, in performing the burn-in test on the semiconductor integrated circuit device 1000 which includes semiconductor chips having different bathtub characteristics, suitable stresses can be applied to the respective semiconductor chips. As a result, for example, it is possible to reduce the number of cases where a semiconductor integrated circuit device which includes a semiconductor chip having an initial failure is shipped due to lack of stress applied to semiconductor chips in the burn-in test. It is also possible to reduce the number of semiconductor chips which become defective semiconductor chips in the burn-in test due to an excessive stress and hence, lowering of a yield rate of semiconductor integrated circuit devices can be suppressed.

### Embodiment 2

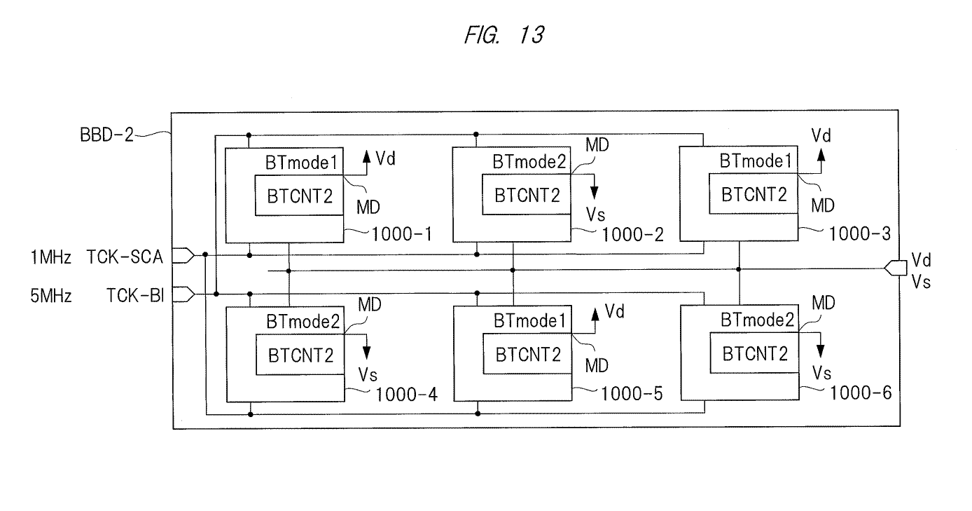

FIG. 13 is a block diagram showing the configuration of a burn-in board BBD-2 according to a second embodiment. FIG. 13 shows a state where a plurality of semiconductor integrated circuit devices 1000-1 to 1000-6 are mounted on a burn-in board BBD-2. The plurality of semiconductor integrated circuit devices 1000-1 to 1000-6 have substantially the same configuration as the semiconductor integrated circuit device described in the first embodiment except for the configuration of a burn control circuit.

A burn-in control circuit BTCNT2 in the second embodiment is similar to the burn-in control circuit BTCNT shown in FIG. 6 so that the configuration of the burn-in control circuit BTCNT2 is described with reference to FIG. 6. The burn-in control circuit BTCNT2 does not have burn-in time counter circuits SBTCT, SCACT and DBTCT shown in FIG. 6, but has a burn-in test sequence circuit BTSQN2 (not shown in the drawing) having the configuration similar to the configuration of the burn-in test sequence circuit BTSQN shown in FIG. 6. Since the burn-in control circuit BTCNT2 does not have the burn-in time counter circuits SBTCT, SCACT and DBTCT, the burn-in control circuit BTCNT2 does not require time counting clock signals BTCKS, BTCKL, BTCKD.

The burn-in test sequence circuit BTSQN shown in FIG. 6 generates enable signals in order from a D enable signal DEB, an L enable signal LEN and an S enable signal SEB when an operation mode (“(4) DBT, SCA, SBT sequential operation”) is designated in response to a burn-in mode control signals MODE0, MODE′. To the contrary, the burn-in test sequence circuit BTSQN2 according to this embodiment changes the order of generating enable signals in accordance with a voltage of a mode control terminal MD when an operation mode (“(4) DBT, SCA, SBT sequential operation”) is designated. That is, when a power source voltage Vd is supplied to the mode control terminal MD, the burn-in test sequence circuit BTSQN2 determines that a burn-in mode BTmodel is designated. As a result, a logic value of the L enable signal LEB is set to “1” (the L enable signal LEB is generated) and, after a predetermined time elapses, a logic value of the L enable signal LEB is set to “0”. After the logic value of the L enable signal LEB is set to “0”, a logic value of the D enable signal DEB and a logic value of the S enable signal SEB are respectively set to “1” (the D enable signal DEB and the S enable signal SEB are generated). After a predetermined time elapses, the logic value of the D enable signal DEB and the logic value of the S enable signal SEB are respectively set to “0”. Thereafter, the logic value of the L enable signal LEB is set to “1” again, and these operations are repeated until a reset signal is supplied thereafter, for example.

On the other hand, when a ground voltage Vs is supplied to the mode control terminal MD, the burn-in test sequence circuit BTSQN2 determines that a burn-in mode BTmode2 is designated, and a logic value of the D enable signal DEB and a logic value of the S enable signal SEB are respectively set to “1” (the D enable signal DEB and the S enable signal SEB are generated). After a predetermined time elapses, the logic value of the D enable signal DEB and the logic value of the S enable signal SEB are respectively set to “0”. After the logic value of the D enable signal DEB and the logic value of the S enable signal SEB are respectively set to “0”, the logic value of the L enable signal LEB is set to “1” (the L enable signal LEB is generated). After a predetermined time elapses, the logic value of the L enable signal LEB is set to “0”. Thereafter, the logic value of the D enable signal DEB and the logic value of the S enable signal SEB are respectively set to “1” again, and these operations are repeated until a reset signal is supplied thereafter, for example.

The burn-in control circuit BTCLN2 receives a burn-in clock signal for logic scanning TCK-SCA and a burn-in clock signal for built-in scanning TCK-BI in place of the burn-in clock signal TCK. The burn-in clock signal TCK-SCA is supplied to the test circuit SCA in place of the burn-in internal clock signal BTCK, and the burn-in clock signal TCK-BI is supplied to the test circuits DBT and SBT in place of the burn-in internal clock signal BTCK.

With such operations, when the logic value of the L enable signal LEB is set to “1”, the test circuit SCA generates a control signal and a test pattern in response to the burn-in clock signal TCK-SCA. The logic circuit is also operated in response to the burn-in clock signal TCK-SCA. On the other hand, when the logic value of the D enable signal DEB and the logic value of the S enable signal SEB are respectively set to “1”, the test circuits DBT and SBT generate test patterns in response to the burn-in clock signal TCK-BI. The dynamic memory DRAM and the static memory SRAM are operated in response to the burn-in clock signal TCK-BI.

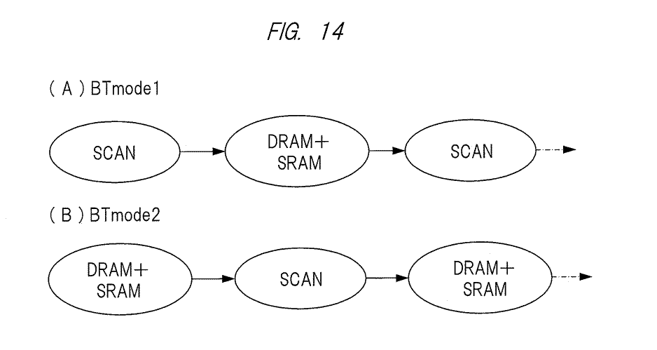

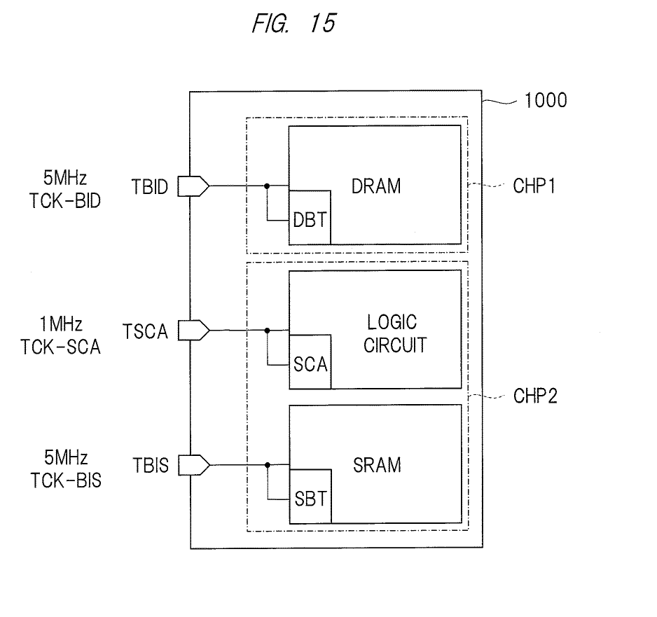

FIG. 14 is a view showing an operation sequence of a burn-in mode which is determined in accordance with a voltage supplied to the mode control terminal MD. FIG. 14(A) shows an operation sequence when the burn-in mode BTmodel is designated, and FIG. 14(B) shows an operation sequence when the burn-in mode BTmode2 is designated. In FIG. 14, “SCAN” indicates that the logic circuit is operated in accordance with a test pattern from the test circuit SCA. “DRAM+SRAM” indicates that the dynamic memory DRAM and the static memory SRAM are operated in accordance with test patterns from the test circuits DBT and SBT.

As shown in FIG. 13, the mode control terminal MD of each of the semiconductor integrated circuit devices 1000-1 to 1000-6 is connected to a power source voltage Vd or a ground voltage Vs of the burn-in board BBD-2. In this embodiment, voltages supplied to the respective mode control terminals MD of the burn-in control circuits BTCNT2 are set such that the burn-in mode BTmodel and the burn-in mode BTmode2 coexist. That is, in the semiconductor integrated circuit devices 1000-1 to 1000-6 mounted on the burn-in board BBD-2, the burn-in mode BTmodel and the burn-in mode BTmode2 coexist. In this embodiment, the semiconductor integrated circuit devices 1000-1, 1000-3 and 1000-5 are set in a burn-in mode BTmodel, and the semiconductor integrated circuit devices 1000-2, 1000-4 and 1000-6 are set in a burn-in mode BTmode2.

With such mode setting, the semiconductor integrated circuit devices 1000-1, 1000-3 and 1000-5 are respectively operated in accordance with the sequence shown in FIG. 14(A), and the semiconductor integrated circuit devices 1000-2, 1000-4 and 1000-6 are respectively operated in accordance with the sequence shown in FIG. 14(B). Accordingly, for example, in a state where the logic circuit is operated in the respective semiconductor integrated circuit devices 1000-1, 1000-3 and 1000-5 (“SCAN” in FIG. 14), the dynamic memory DRAM and the static memory SRAM are operated in the respective semiconductor integrated circuit devices 1000-2, 1000-4 and 1000-6 (“DRAM+SRAM” in FIG. 14). On the other hand, in a state where the dynamic memory DRAM and the static memory SRAM are operated in the respective semiconductor integrated circuit devices 1000-1, 1000-3 and 1000-5 (“DRAM+SRAM” in FIG. 14), the logic circuit is operated (“SCAN” in FIG. 14) in the respective semiconductor integrated circuit devices 1000-2, 1000-4 and 1000-6.

With such a configuration, in the semiconductor integrated circuit devices 1000-1 to 1000-6, it is possible to prevent the occurrence of a state where the same circuits are frequently operated at substantially the same time. Accordingly, a peak power consumed by the burn-in board BBD-2 can be lowered. As a result, a power capacity of the control device BBDCNT mounted on the burn-in test device 1100 (FIG. 11) can be lowered.

In the second embodiment, a terminal to which a burn-in clock signal TCK-SCA is supplied and a terminal to which a burn-in clock signal TCK-BI is supplied are mounted on the burn-in board. The burn-in clock signals TCK-SCA, TCK-BI are supplied to the respective burn-in control circuits BTCNT2 from the control device BBDCNT through these terminals (FIG. 11). By changing frequencies of the burn-in clock signals TCK-SCA, TCK-BI generated by the control device BBDCNT, an operation speed of the dynamic memory DRAM and an operation speed of the static memory SRAM and an operation speed of the logic circuit can be changed. For example, by increasing a frequency of the burn-in clock signal TCK-SCA, an operation speed of the logic circuit can be increased. By increasing a frequency of the burn-in clock signal TCK-BI, operation speeds of the dynamic memory DRAM and the static memory SRAM can be respectively increased. On the other hand, by lowering a frequency of the burn-in clock signal TCK-SCA, an operation speed of the logic circuit can be lowered. By lowering a frequency of the burn-in clock signal TCK-BI, operation speeds of the dynamic memory DRAM and the static memory SRAM can be respectively lowered. Further, an operation speed of the logic circuit and operation speeds of the dynamic memory DRAM and the static memory SRAM can be controlled separately.

Accordingly, even when a time during which a logic value of an L enable signal LEB is set to “1”, a time during which a logic value of a D enable signal DEB is set to “1” and a time during which a logic value of an S enable signal SEB is set to “1” are respectively set to predetermined times (fixed times, for example), an amount of stress applied to the dynamic memory DRAM, an amount of stress applied to the static memory SRAM and an amount of stress applied to the logic circuit in the burn-in test can be controlled by changing frequencies of the burn-in clock signals TCK-SCA, TCK-BI. That is, by increasing a frequency of the burn-in clock signal TCK-SCA, an amount of stress which the logic circuit generates is increased so that an amount of stress applied to the semiconductor chip CHP2 can be increased. In the same manner, by increasing a frequency of the burn-in clock signal TCK-BI, an amount of stress applied to a semiconductor chip CHP1 on which the dynamic memory DRAM is formed and an amount of stress applied to a semiconductor chip CHP2 on which the static memory SRAM is formed can be increased.

Frequencies of these burn-in clock signals are set in accordance with bathtub characteristics of the respective semiconductor chips CHP1, CHP2. As one example, a frequency of the burn-in clock signal TCK-SCA is set to 1 MHz, and a frequency of the burn-in clock signal TCK-BI is set to 5 MHz.

In the second embodiment, the dynamic memory DRAM and the static memory SRAM are substantially simultaneously operated in the burn-in test and hence, a time required for performing the burn-in test can be shortened.

### Embodiment 3

FIG. 15 is a block diagram showing the configuration of a semiconductor integrated circuit device 1000 according to a third embodiment. The semiconductor integrated circuit device 1000 shown in FIG. 15 is similar to the semiconductor integrated circuit device shown in FIG. 4. Accordingly, in this embodiment, points which make the semiconductor integrated circuit device 1000 shown in FIG. 15 different from the semiconductor integrated circuit device shown in FIG. 4 are mainly described.

The semiconductor integrated circuit device 1000 according to the third embodiment does not have a burn-in control circuit BTCNT, but has terminals TBID, TSCA and TBIS. In performing a burn-in test, a burn-in clock signal TCK-BID for a dynamic memory DRAM is supplied to the terminal TBID, a burn-in clock signal for a logic circuit TCK-SCA is supplied to the terminal TSCA, and a burn-in clock signal for a static memory SRAM TCK-BIS is supplied to the terminal TBIS. In performing the burn-in test, a burn-in clock signal TCK-BID is supplied to a dynamic memory RDAM and a test circuit DBT through the terminal TBID. Further, a burn-in clock signal TCK-SCA is supplied to a logic circuit and a test circuit SCA through the terminal TSCA. The burn-in clock signal TCK-BIS is supplied to a static memory SRAM and a test circuit SBT through the terminal IBIS.

In the third embodiment, in performing the burn-in test, the control device BBDCNT (FIG. 11) generates and supplies burn-in clock signals TCK-BID, TCK-SCA and TCK-BIS. In this case, a frequency of the burn-in clock signal TCK-BID is set to 5 MHz, for example. A frequency of the burn-in clock signal TCK-SCA is set to 1 MHz, for example. A frequency of the burn-in clock signal TCK-BIS is set to 5 MHz, for example.

The dynamic memory DRAM and the test circuit DBT of the dynamic memory DRAM are operated in response to a burn-in clock signal TCK-BID. The logic circuit and the test circuit SCA of the logic circuit are operated in response to a burn-in clock signal TCK-SCA. The static memory SDRAM and the test circuit SBT of the static memory SDRAM are operated in response to a burn-in clock signal TCK-BIS. By making the burn-in clock signal for operating the dynamic memory DRAM and the test circuit DBT of the dynamic memory DRAM, the burn-in clock signal for operating the logic circuit and the test circuit SCA of the logic circuit, and the burn-in clock signal for operating the static memory SDRAM and the test circuit SBT of the static memory SDRAM differ from each other, amounts of stresses generated in the circuits which are operated in response to the respective burn-in clock signals can be controlled separately. That is, an amount of stress generated in the circuit at the time of performing the burn-in test can be reduced by lowering a frequency of the burn-in clock signal. On the other hand, an amount of stress generated in the circuit at the time of performing the burn-in test can be increased by increasing a frequency of the burn-in clock signal.

For example, an amount of stress applied to the semiconductor chip CHP2 can be reduced by lowering a frequency of the burn-in clock signal TCK-SAC supplied to the logic circuit formed on the semiconductor chip CHP2. Accordingly, even when a bathtub characteristic of the semiconductor chip CHP2 is shorter than a bathtub characteristic of the semiconductor chip CHP1, at the time of performing the burn-in test, an amount of stress applied to the semiconductor chip CHP2 can be reduced.

In the third embodiment, at the time of performing the burn-in test, the dynamic memory DRAM, the static memory SRAM and the logic circuit are substantially simultaneously operated and hence, a time required for performing the burn-in test can be further shortened.

In the foregoing, the invention made by the present inventor has been concretely described based on the embodiments. However, it is needless to say that the present invention is not limited to the foregoing embodiments and various modifications and alterations can be made within the scope of the present invention.

By obtaining bathtub characteristics of the respective semiconductor chips CHP1 and CHP2 in advance, it may possible to configure the burn-in control circuit BTCNT such that the burn-in control circuit BTCNT has only an operation mode “(4) DBT, SCA, SBT sequential operation”. In this case, it is sufficient that a dwell time and frequencies of the time counting clock signals BTCKS, BTCKL, BTCKD are respectively set so as to conform to the bathtub characteristics which are obtained in advance. By allowing the burn-in control circuit BTCNT to have only one operation mode, the configuration of the burn-in control circuit BTCNT can be simplified and hence, it is possible to suppress the rise of cost of the semiconductor chip CHP2.

In the second embodiment, operation speeds of the logic circuit, the dynamic memory DRAM and the static memory SRAM are determined in response to burn-in clock signals TCK-SCA, TCK-BI. However, a dwell time may be changed in the same manner as the first embodiment.

<Note>

Although a plurality of inventions are disclosed in this specification and some of the inventions are described in Claims, this specification also discloses inventions other than the inventions described in Claims. Representative inventions among other inventions are enumerated hereinafter.

(A) A semiconductor integrated circuit device including: a first semiconductor chip having a first circuit; a second semiconductor chip having a second circuit and differing from the first semiconductor chip; and a substrate on which the first semiconductor chip and the second semiconductor chip are mounted, in which

the semiconductor integrated circuit device further includes:

a first designating circuit which designates a time during which the first circuit of the first semiconductor chip is operated in a burn-in test; and

a second designating circuit which designates a time during which the second circuit of the second semiconductor chip is operated in the burn-in test.

(B) The semiconductor integrated circuit device described in (A), in which

the first designating circuit and the second designating circuit are included in the second semiconductor chip,

the first designating circuit includes a first counter circuit to which a first clock signal a frequency of which is changed corresponding to a period during which the first circuit is operated is supplied, and in the semiconductor integrated circuit device, whether or not an operation of the first circuit is to be stopped is determined based on whether or not a count value of the first counter circuit reaches a predetermined value, and

the second designating circuit includes a second counter circuit to which a second clock signal a frequency of which is changed corresponding to a period during which the second circuit is operated is supplied, and in the semiconductor integrated circuit device, whether or not an operation of the second circuit is to be stopped is determined based on whether or not a count value of the second counter circuit reaches a predetermined value.

(C) The semiconductor integrated circuit device described in (B), in which the first semiconductor chip and the second semiconductor chip have bathtub characteristics which differ from each other.

(D) A semiconductor integrated circuit device including: a first semiconductor chip having a first circuit; a second semiconductor chip having a second circuit and differing from the first semiconductor chip; and a substrate on which the first semiconductor chip and the second semiconductor chip are mounted, in the semiconductor integrated circuit device,

the semiconductor integrated circuit device further includes a control circuit which is connected to a mode control terminal, and controls the first circuit and the second circuit in accordance with a voltage supplied to the mode control terminal in a burn-in test,

the control circuit operates the second circuit when the mode control terminal is at a first voltage, and the control circuit operates the first circuit after the operation of the second circuit is stopped, and

the control circuit operates the first circuit when the mode control terminal is at a second voltage, and the control circuit operates the second circuit after the operation of the first circuit is stopped.

(E) The semiconductor integrated circuit device described in (D) in which,

the first circuit is operated in response to a first signal having a first frequency in a burn-in test, and the second circuit is operated in response to a second signal having a second frequency which differs from the first frequency in the burn-in test.

(F) A semiconductor integrated circuit device including: a first semiconductor chip having a first circuit; a second semiconductor chip having a second circuit and differing from the first semiconductor chip; and a substrate on which the first semiconductor chip and the second semiconductor chip are mounted, in the semiconductor integrated circuit device,

the semiconductor integrated circuit device further includes:

a first terminal to which a first signal having a first frequency is supplied in a burn-in test; and

a second terminal to which a second signal which differs from the first frequency is supplied in the burn-in test, and

in the burn-in test, the first circuit is operated in response to the first signal, and the second circuit is operated in response to the second signal.

(G) The semiconductor integrated circuit device described in (F), in which the first semiconductor chip and the second semiconductor chip have bathtub characteristics which differ from each other.

(H) A method of manufacturing a semiconductor integrated circuit device including:

a preparing step of preparing a plurality of first semiconductor chips each having a first circuit and a plurality of second semiconductor chips each differing from the first semiconductor chip and having a second circuit;

a step of forming the plurality of semiconductor integrated circuit devices by mounting each of the plurality of first semiconductor chips and each of the plurality of second semiconductor chips prepared in the preparing step on one substrate; and

a burn-in step of mounting the plurality of respective semiconductor integrated circuit devices on one burn-in board and performing a burn-in test on the plurality of semiconductor integrated circuit devices while supplying a power source voltage to the burn-in board, in the method,

the first semiconductor integrated circuit device of the plurality of semiconductor integrated circuit devices mounted on one burn-in board has a first sequence circuit which, in the burn-in step, operates the first circuit of the first semiconductor chip, and operates the second circuit of the second semiconductor chip after stopping the operation of the first circuit, and

the second semiconductor integrated circuit device which differs from the first semiconductor integrated circuit device of the plurality of semiconductor integrated circuit devices mounted on one burn-in board has a second sequence circuit which, in the burn-in step, operates the second circuit of the second semiconductor chip, and operates the first circuit of the first semiconductor chip after stopping the operation of the second circuit, and

the first sequence circuit and the second sequence circuit prevent the first circuit of the first semiconductor integrated circuit device and the first circuit of the second semiconductor integrated circuit device from being operated in an overlapping manner with time.

(I) The method of manufacturing a semiconductor integrated circuit device described in (H), in which

the second semiconductor chip on the first semiconductor integrated circuit device and the second semiconductor chip of the second semiconductor integrated circuit device further has a third circuit respectively,

the first sequence circuit operates the first circuit or the third circuit of the first semiconductor integrated circuit device when the second circuit is operated in the second semiconductor integrated circuit device, and the second sequence circuit operates the first circuit or the third circuit of the second semiconductor integrated circuit device when the second circuit is operated in the first semiconductor integrated circuit device.

(J) The method of manufacturing a semiconductor integrated circuit device described in (I), in which

the first circuit is formed of a dynamic memory, the second circuit is formed of a static memory, and the third circuit is formed of a logic circuit, and a power source voltage supplied to the burn-in board is supplied to the plurality of respective semiconductor integrated circuit devices.

(K) The method of manufacturing a semiconductor integrated circuit device described in (J), in which

the first semiconductor chip and the second semiconductor chip have bathtub characteristics which differ from each other.

(L) The method of manufacturing a semiconductor integrated circuit device described in (H), in which

the first circuit is operated in response to a first signal having a first frequency, and the second circuit is operated in response to a second signal having a second frequency different from the first frequency.

### REFERENCE SIGNS LIST

1000 Semiconductor integrated circuit device
1100 Burn-in test device BTCNT burn-in control circuit
CHP1, CHP2 Semiconductor chip DBT, SBT, SCA test circuit
DRAM Dynamic memory
SRAM Static memory

1. A semiconductor integrated circuit device comprising: a first semiconductor chip having a first circuit; and a second semiconductor chip having a second circuit and differing from the first semiconductor chip,
wherein the semiconductor integrated circuit device further comprises a control circuit for controlling an operation of the first circuit and an operation of the second circuit in accordance with a control signal in a burn-in test, and
the control circuit controls the first circuit and the second circuit such that an amount of stress applied to the first semiconductor chip due to the operation of the first circuit and an amount of stress applied to the second semiconductor chip due to the operation of the second circuit differ from each other in the burn-in test.

2. The semiconductor integrated circuit device according to claim 1,
wherein the first semiconductor chip and the second semiconductor chip have different bathtub characteristics, and the second semiconductor chip has the control circuit.

3. The semiconductor integrated circuit device according to claim 2,
wherein, in the burn-in test, the control circuit makes a time during which the first circuit is operated differ from a time during which the second circuit is operated d in accordance with the control signal.

4. The semiconductor integrated circuit device according to claim 2,
wherein, in the burn-in test, the control circuit is makes an operation speed of the first circuit differ from an operation speed of the second circuit in accordance with the control signal.

5. A semiconductor integrated circuit device comprising: a first semiconductor chip having a first circuit; a second semiconductor chip having a second circuit and differing from the first semiconductor chip; and a substrate on which the first semiconductor chip and the second semiconductor chip are mounted,
wherein the semiconductor integrated circuit device further comprises a control circuit which, in the burn-in test, selectively operates the first circuit in the first semiconductor chip and the second circuit in the second semiconductor chip in accordance with a mode signal, and
the control circuit performs a control so as to prevent the first circuit in the first semiconductor chip and the second circuit in the second semiconductor chip from operating in an overlapping manner with time.

6. The semiconductor integrated circuit device according to claim 5,
wherein the control circuit includes a sequence circuit for operating the second circuit in the second semiconductor chip after the first circuit in the first semiconductor chip is operated.

7. The semiconductor integrated circuit device according to claim 6,
wherein the semiconductor integrated circuit device further comprises:
a first designating circuit coupled to the sequence circuit and designating a period during which the first circuit is operated; and
a second designating circuit coupled to the sequence circuit and designating a period during which the second circuit is operated.

8. The semiconductor integrated circuit device according to claim 7,
wherein the first semiconductor chip includes a first test circuit for receiving a clock signal and a first enable signal and operating the first circuit in accordance with the clock signal with the supply of the first enable signal, and
the second semiconductor chip includes a second test circuit for receiving the clock signal and a second enable signal and operating the second circuit in accordance with the clock signal with the supply of the second enable signal, and
the sequence circuit generates the first enable signal during the period designated by the first designating circuit and generates the second enable signal during the period designated by the second designating circuit.

9. The semiconductor integrated circuit device according to claim 8,
wherein the control circuit includes the first designating circuit and the second designating circuit,
the control circuit is included in the second semiconductor chip,
the first designating circuit includes a first counter circuit to which a first clock signal a frequency of which is changed corresponding to a period during which the first circuit is operated is supplied, and whether or not an operation of the first circuit is to be stopped is determined based on whether or not a count value of the first counter circuit reaches a predetermined value, and
the second designating circuit includes a second counter circuit to which a second clock signal a frequency of which is changed corresponding to a period during which the second circuit is operated is supplied, and whether or not an operation of the second circuit is to be stopped is determined based on whether or not a count value of the second counter circuit reaches a predetermined value.

10. The semiconductor integrated circuit device according to claim 9,
wherein the second semiconductor chip further includes:
a third circuit; and
a third test circuit for receiving the clock signal and a third enable signal and operating the third circuit in accordance with the clock signal with the supply of the third enable signal,
the control circuit includes a third counter circuit to which a third clock signal a frequency of which is changed corresponding to a period during which the third circuit is operated is supplied, and
the sequence circuit in the control circuit operates the third circuit by generating the third enable signal after the first circuit is operated and before the second circuit is operated, and whether or not an operation of the third circuit is to be stopped is determined based on whether or not a count value of the third counter circuit reaches a predetermined value.

11. The semiconductor integrated circuit device according to claim 10,
wherein the first circuit is formed of a dynamic memory, the second circuit is formed of a static memory, and the third circuit is formed of a logic circuit, and
the first test circuit and the second test circuit are formed of a BIST circuit respectively, and the third test circuit is formed of a scan pass circuit.

12. A method of manufacturing a semiconductor integrated circuit device comprising:
a preparing step of preparing a first semiconductor chip and a second semiconductor chip which differs from the first semiconductor chip;
a step of forming the semiconductor integrated circuit device by mounting the first semiconductor chip and the second semiconductor chip prepared in the preparing step on one substrate; and
a burn-in step of mounting the semiconductor integrated circuit device on a burn-in board and performing a burn-in test,
wherein the first semiconductor chip has a first circuit, the second semiconductor chip has a second circuit, the semiconductor integrated circuit device has a sequence circuit, and the first circuit in the first semiconductor chip is operated and the second circuit in the second semiconductor chip is operated after an operation of the first circuit is stopped by the sequence circuit in the burn-in step.

13. The method of manufacturing a semiconductor integrated circuit device according to claim 12,
wherein the first semiconductor chip includes a first test circuit for receiving a clock signal and a first enable signal and operating the first circuit in accordance with the clock signal with the supply of the first enable signal,
the second semiconductor chip includes: a second test circuit which for receiving the clock signal and a second enable signal and operating the second circuit in accordance with the clock signal with the supply of the second enable signal; and the sequence circuit, and
the sequence circuit generates the second enable signal after generating the first enable signal.

14. The method of manufacturing a semiconductor integrated circuit device according to claim 13,
wherein the sequence circuit includes:
a first designating circuit for designating a time during which the first enable signal is generated; and
a second designating circuit for designating a time during which the second enable signal is generated.

15. The method of manufacturing a semiconductor integrated circuit device according to claim 14,
wherein the first semiconductor chip and the second semiconductor chip have bathtub characteristics which differ from each other.
